(19) United States
(12) Patent Application Publication
(10) Pub. No.: US 2015/0036234 A1
(43) Pub. Date: Feb. 5, 2015

(54) METHODS AND COMPOSITIONS RELATED TO DIELECTRIC COATED METAL NANOPARTICLES IN THIN-FILM OPTO-ELECTRONIC CONVERSION DEVICES

(71) Applicant: Board Of Regents, The University Of Texas System, Austin, TX (US)

(72) Inventors: Adela Ben-Yakar, Austin, TX (US); Richard K. Harrison, Austin, TX (US)

(21) Appl. No.: 14/449,751

(22) Filed: Aug. 1, 2014

Related U.S. Application Data
(60) Provisional application No. 61/861,150, filed on Aug. 1, 2013.

(51) Int. Cl. G02B 5/20; H01L 31/18; H01L 31/052; H01L 49/00; H01G 9/20; H01L 31/0232; H01L 51/44

(52) U.S. Cl. CPC G02B 5/206; H01L 31/02325; H01L 31/18; H01L 51/447; H01L 49/006; H01G 9/209; H01L 31/0522
USPC 359/885; 257/432; 438/69; 257/40; 427/162

(57) ABSTRACT

Disclosed are compositions and methods for making and using thin film opto-electronic conversion devices using nanoparticles.

### CROSS-REFERENCE TO RELATED APPLICATIONS

This application claims benefit of U.S. Provisional Application No. 61/861,150, filed Aug. 1, 2013, which is hereby incorporated by reference in its entirety.

### STATEMENT REGARDING FEDERALLY SPONSORED RESEARCH OR DEVELOPMENT

This invention was made with Government support under Grant No. CBET-1014953 awarded by the National Science Foundation, and under Grant No. RO1AG041135 awarded by the National Institutes of Health. The Government has certain rights in the invention

### TECHNICAL FIELD

This application relates generally to dielectric coated metal nanoparticles for the plasmonic enhancement of thin film solar cells through increased optical absorption.

### BACKGROUND

More than 120 petajoules (PJ, 1 PJ=1×10¹⁵ J) of solar energy strike the Earth's surface every second. More solar energy reaches the Earth's surface in 90 minutes than is consumed by the entire world population in a year from all sources combined. Given the bounty of solar energy, it has long been a dream to harness this clean and renewable energy source for useful purposes. The first practical solar cell was developed in 1954, but the usage of solar cells was largely confined to ‘off-grid’ applications due to high costs and low efficiencies for the next few decades. Steady decreases in the costs and increases in the efficiency of conventional silicon solar modules made impressive advances over the years, but photovoltaic power remained economically impractical in comparison with utility power from other sources.

Over the years, many efforts have been made to reduce material usage as a means of cutting costs, but it was not until the disruptive commercial introduction in the early 2000's of low cost thin film solar cells that made compelling material cost reductions possible. Thin film solar cells are chemically deposited rather than sliced from a boule, which dramatically improves the economic viability of solar photovoltaics. They have significant advantages over standard ‘thick’ crystalline wafer-based silicon solar cells in fabrication cost, material usage, and energy payback, while maintaining a crucial advantage in the cost-to-power ratio (dollars per watt, $/W). Other benefits of this type of cells include the ability to fabricate the cells on durable and flexible substrates, or to incorporate the solar cells into buildings (BIPV). Thin film solar devices represent one of the fastest growing segments of a multi-billion dollar industry, largely based on advantages in production volumes and cost efficiency advantages on a $/Watt basis.

Despite all of these innovations and even including substantial government subsidies, solar energy is currently only cost-competitive with utility scale power in a few regions of the United States on a levelized cost of energy (LCOE) basis. To achieve widespread use, however, solar costs need to reach true grid parity, for which significant new advances need to occur. Expanded availability of low cost solar photovoltaics could have tremendous implications worldwide for the environment, electricity production in third world nations, and health.

While thin film solar cells are superior on a $/W basis, they still trail in the overall efficiency of wafer-based silicon solar materials. This difference is largely based on the poor conversion efficiency of thin film solar cells in the red-near infrared (NIR) wavelength range, which carries almost half of the useful solar irradiation at the Earth's surface. Thin film solar cells are characterized by extremely low efficiencies at long wavelengths because of the absorption path length can be large relative to the film thickness. Another cause of low absorption in thin-film devices is that existing light-trapping technologies used in conventional solar cells are not relevant for thin film solar devices. The poor absorption of these materials in the long wavelength portion of the solar spectrum is due to the trend in semiconductor devices of increasingly long absorption lengths as the wavelength increases. As the cell thickness decreases, the longer absorption length of near-infrared light leads to the low conversion efficiency of light to useful energy in this range. Interestingly, this near-band-gap light is the most efficiently converted light, as only one band-gap of energy can be efficiently harvested from any photon, regardless of the incident energy. Together, these factors show that there is a problem to be solved and an attractive opportunity for boosting the conversion efficiency of long-wavelength light for thin film solar cells.

Plasmonic solar enhancement is an emerging scientific field that makes use of the extraordinary optical properties of noble metallic nanoparticles to improve the efficiency of solar cells. Plasmonic nanoparticles have a resonant interaction with light that matches the plasmon frequency of the particle. At this frequency, the particle acts as a nano-antenna, gathering light from an area much larger than the particle itself, generating high intensities by concentrating the electromagnetic energy in the near-field and redirecting optical energy in new directions through scattering. The plasmon frequency depends on the size, shape, material, and surrounding environment of the particle. These parameters can also be used to tune the way that the particle interacts with the incident light, shifting the ratio of scattering to absorption and the angular distribution of scattered light. The ability to modify the interaction behavior can be of the utmost importance when employing these particles for practical purposes. Plasmonic optical interactions could potentially be of great benefit through improving the absorption of light in optical absorption-limited thin film solar cells. Lithographic approaches, such as electron-beam (e-beam) deposition, are the gold standard methods for creating designed nanostructures for creating plasmonic nanoparticles or nanostructures on a surface. However, the cost and time constraints on lithography are fundamentally limiting, meaning that lithographic nanostructure fabrication cannot be currently be accomplished on wide enough scale for medical or solar applications. Colloidal synthesis of metallic nanoparticles, however, is a technique with a wide range of advantages for the creation of plasmonic nanostructures for photovoltaic applications. Metal nanoparticle synthesis is inexpensive, achievable with common laboratory equipment and chemicals, and can be used to fabricate a wide range of metal nanostructures. These particles can be stabilized in aqueous or organic solvents for time periods measured in centuries. Various reducing agents can be used to synthesize metal nanoparticles, including environmentally-friendly, biologically-derived reducing agents. Furthermore, unlike metal particles deposited by sputtering, the energy requirements are very low, as no vacuum conditions or high temperature annealing is necessary to achieve desired nanoparticle sizes. Nanoparticles can be applied on solid substrates using spray techniques, drop-casting or self-assembly, although obtaining uniform, evenly spaced nanoparticle depositions can be challenging.

One of the primary advantages of colloidally synthesized metal nanoparticles is the degree of control that can be obtained over the size and shape of the particle. Nanorods, branched structures, discs, triangular prisms, wires, spheres, and ovoids are among the many types of plasmonic metal nanoparticles synthesized to date. The size of particles synthesized using wet-chemistry methods can range from a nanometer to several hundred nanometers. Furthermore, shell coatings with homogenous thicknesses can be grown on top of the nanoparticle, even leading to three layer structures and more. The shell materials can be metal or dielectric materials.

Plasmonic nanoparticles can have a strong effect on the light collection within a thin film solar cell by scattering light perpendicular to the incident direction to promote guided modes within the optical absorber material, effectively increasing the optical thickness of a thin-film solar cell. Various strategies for the use of plasmonic nanostructures have been suggested, but it has been unclear how these methods can be used to definitively improve the overall performance of a solar cell. For example, nanoparticles placed on top of the optical absorbing layer of a photovoltaic cell have been shown to cause significant optical losses at certain wavelengths by backscattering and reduced optical coupling into the optical absorption layer. Another major challenge for plasmonic photovoltaic devices that has remained unaddressed to date is that exposed, unshielded metal surfaces in contact with semiconductor materials have been conclusively shown to act as recombination sites that can significantly reduce the charge collection and corresponding ultimate efficiency of a solar cell. Common techniques for addressing this problem is through the use of targeted heavy doping at metal contacts, but this approach would is not be feasible for the nanoscale size domains of plasmonic nanoparticles.

What is needed in the art is a method to improve the effectiveness of thin film opto-electronic conversion devices utilizing plasmonic enhancement. Herein, we disclose a new concept of using dielectric-coated plasmonic metal nanoparticles to provide the benefits of improved plasmonic optical absorption in thin-film solar cells while also mitigating the issue of metal surface recombination. We also disclose efficient and effective methods of synthesizing these nanoparticles and thin film opto-electronic conversion devices incorporating these particles.

### SUMMARY

Disclosed herein is a thin film opto-electronic conversion device, comprising: a substrate; a pair of conductive layers arranged on the substrate; at least one optical absorbing layer arranged between the pair of conductive layers; and one or more types of dielectric-coated metal plasmonic nanoparticles embedded in the optical absorbing layer, wherein the plasmonic nanoparticles have at least one characteristic that increases optical absorption of the optical absorbing layer.

Also disclosed herein is a plasmonic nanoparticle 3101 for use with an optical absorbing material (3206, 3205) in an opto-electronic conversion device (3211), comprising: a metal core (3102); and a dielectric layer (3103), wherein the dielectric layer is coated over at least a portion of an outer surface of the metal core, the plasmonic nanoparticles being embedded in the optical absorbing materials (3206, 3205) and having at least one characteristic that increases optical absorption of the optical absorbing material. Further disclosed herein is a method of manufacturing a thin film opto-electronic conversion device, comprising: providing a substrate (3208); forming a pair of conductive layers (3207, 3204) arranged on the substrate; forming one or more optical absorbing layers (3206, 3205) between the pair of conductive layers; forming a thin surface functionalization agent layer (3209); and embedding one or more types of dielectric coated plasmonic nanoparticles (3210) in between the optical absorbing layers, wherein the plasmonic nanoparticles have at least one characteristic that increases optical absorption of the optical absorbing layer. The functionalization agent layer (3209) can be removed after the nanoparticles (3210) are attached on the surface without disturbing the nanoparticles. The absorbing layers can then be deposited over the nanoparticles so that they are embedded inside the absorbing layer.

Also disclosed herein is a method of manufacturing one or more plasmonic nanoparticles, comprising: forming a metal core; and coating a dielectric layer over at least a portion of an outer surface of the metal core, wherein the plasmonic nanoparticles have at least one characteristic that increases optical absorption of an optical absorbing material when embedded therein.

### BRIEF DESCRIPTION OF THE FIGURES

The accompanying Figures, which are incorporated in and constitute a part of this specification, illustrate several aspects of the invention and together with the description serve to explain the principles of the invention.

FIG. 1 shows absorbance spectra of gold nanoparticles synthesized using a kinetic ripening approach. All nanoparticles were measured as synthesized without any purification processes. The first curve represents the initially synthesized seeds (101), while the remaining lines (102, 103, 104, 105, 106, 107, 108, and 109) show the samples taken at various growth stages. The legend shows the growth step (GS) number with the predicted size (using Equation 1) shown in parentheses.

FIG. 2 shows gold nanoparticles of various sizes synthesized with kinetic control. The top images for all nanoparticles are transmission-mode STEM micrographs of representative nanoparticles for samples prepared using a) 1, b) 3, c) 6, and d) 9 growth steps. The scale bars are 100 nm. The histograms below show the distribution of measured particles, along with the number of measurements, N. The average diameter, D, of the particles together with standard deviation is also presented.

FIG. 3 shows a comparison of absorbance spectra of 50 nm gold nanoparticles. The BBI nanoparticles (301) were purchased from a commercially available source. The other particles (302, 303) were fabricated in house using one-step and kinetic ripening synthesis protocols, respectively.

FIG. 4 shows a seeded growth synthesis of silver nanoparticles of various sizes using kinetic control. a) The citrate-only seeded growth synthesis procedure yields relatively wide size distribution plasmonic peaks (401, 402, 403, 404). b) Small seeds initially synthesized with sodium borohydride can be grown while maintaining the initial small distribution in nanoparticle size (405, 406, 407, 408, 409, 410).

FIG. 5 shows the peak position and width of narrowly distributed particles can be accurately simulated with only a single particle size. Comparisons of experimental and simulated data for a) 22 nm (501) and b) 30 nm (503) spheres in an aqueous medium.

FIG. 6 shows simulations of 50 nm silver nanoparticles coated with silica shells in water (601, 602, 603, 604, 605) and microcrystalline silicon (606, 607, 608, 609) environments. The curves are named according to the surrounding environment and the silica shell thickness.

FIG. 7 shows microscopy results for a silica shell grown on a silver core. a) STEM micrograph of an isolated particle, where the scale bar is 50 nm. b) Energy dispersive x-ray spectroscopy (EDS) line scan showing the locations of signal corresponding to silver (702) and silicon (701) in the nanoparticle. The white dashed line in a) is the scan path. Note: oxygen is undetectable with EDS, so only silver and silicon signals are shown.

FIG. 8 shows electron microscopy images of Ag®SiO2 nanoparticles showing the homogeneity of the shell thickness. The scale bar is 100 nm. For this sample, the silica thickness was 19.5±1.2 nm.

FIG. 9 shows experimental spectral shift observed for different thicknesses (901, 902, 903) of silica shells on silver cores. The inset shows the peak shift due to the presence of the thin silica shells. The values indicated are determined from the simulated thickness that provides an equivalent shift in the plasmon peak in a water medium.

FIG. 10 shows scanning electron micrographs of self-assembled monolayers of silver nanoparticles on a glass substrate. a) High resolution zoom of the sub-monolayer of deposited silver nanoparticles. The scale bar is 250 nm. b) Wide-field view of the assembled particles showing the regularity in the deposited pattern over a large area. The scale bar is 2.5 μm.

FIG. 11 shows experimental measurements of 50 nm gold nanoparticles measured on three different spectrometer systems: the new system (1101), the BioTek Synergy HT (1102), and Cary 5000 (1103).

FIG. 12 presents theoretical calculations showing changes in plasmonic properties for a 50 nm gold sphere embedded in various media (1201, 1202, 1203, 1204). a) Plasmon resonance shift and b) single-scattering albedo for gold in water (1204), silicon nitride 1203), cadmium telluride (1202) and microcrystalline silicon (1201).

FIG. 13 shows theoretical calculations of plasmonic response of a 50 nm Ag sphere in different conditions (1301, 1302, 1303, 1304).

FIG. 14 shows theoretical calculations of plasmonic effects for a 54 nm Ag®SiO₂ nanoparticle (50 nm Ag core coated with a 2 nm SiO₂ layer) embedded in photovoltaic semiconductors (1401, 1402, 1403, 1404, and 1405). Wavelength-dependent interaction efficiencies are shown for each of the gain and loss mechanisms for plasmonic nanoparticles in a) μc-Si, and b) CIGS.

FIG. 15 shows calculated wavelength dependence of intensity (irradiance) and particle interaction for a 50 nm silver sphere with a 2 nm silica shell in semiconductors. a) The modified solar spectrum at the particle depth in silicon (1502) and CIGS (1503). b) The net potential particle interaction, given as the total absorption of the medium minus what would be absorbed in the absence of the particle, and the convolved intensity (1505) interacting with a single particle within a CIGS medium at a depth of 125 nm. The convolved intensity is the net potential particle interaction (1504) multiplied by the particle area and incident solar intensity at that location.

FIG. 16 shows calculated plasmonic enhancement of absorption and conversion using embedded Ag®SiO₂ nanoparticles in μc-Si. (a) The enhanced absorption and (b) the enhanced conversion, are shown for 50 nm silver spheres with a 2 nm thick silica shell embedded at the center of a 1 μm thick μc-Si semiconductor layer.

FIG. 17 shows measurements of 250 nm thin silicon films deposited with PE-CVD. a) Optical absorbance of deposited amorphous silicon thin films showing the intra- and inter-batch film consistency. b) Optical constants of deposited amorphous silicon layers deposited via PECVD. The plot shows the experimentally obtained values from ellipsometry measurements along with reference values for amorphous silicon.

FIG. 18 shows a comparison of optical properties of silver nanoparticles in different media (1801, 1802, 1803, 1804) using simulations and experimental observations. The silver nanoparticles are first measured in a colloidal solution. These nanoparticles were then self-assembled on a clean glass slide and a 1 μm SiO₂ layer was deposited on top with PE-CVD.

FIG. 19 shows the spacing in self-assembled sub-monolayers can be controlled with the concentration of the metal nanoparticle colloid. The concentration is a) 25%, b) 50%, and c) 100% of the initial solution. The scale bar represents 250 nm.

FIG. 20 shows measured absorption enhancement for 500 nm thick silicon thin films on account of plasmonic Ag®SiO₂ nanoparticles. The averaged gains over all batches are 7±6%, 17±8%, 15±6%, and 39±11% for the no shell, and shells with thicknesses of 1, 2, and 4 nm cases, respectively. The particles were 35 nm. The concentration was low to avoid agglomeration.

FIG. 21 a shows photograph of plasmon-enhanced photodetectors fabricated on ITO-coated glass slides. All four substrates are coated with a silver top electrode. The top left and bottom right substrates are controls (no nanoparticles), while the bottom left and top right semiconductor layers have Ag®SiO₂ nanoparticles embedded in the Si layer.

FIG. 22 shows a comparison of silver particles synthesized with the modified DR-SKSG (seeded growth, 2202) and the Turkevich method (one-step synthesis, 2203) to theoretically predicted values (2201). The peak position and width of narrowly distributed particles obtained with the new method can be accurately simulated with only a single particle size. A comparisons of experimental and simulated data for nominally 50 nm diameter silver particles shows that the modified dual reducing agent SKSG technique proposed here yields significantly narrower size distribution particles than the Turkevich method.

FIG. 23 shows the modified DR-SKSG method for the synthesis of mono-dispersed silver particles: (a) Synthesis diagram and (b) image showing a collection of silver nanoparticle solutions grown with the DR-SKSG technique. The change in plasmonic resonance and corresponding nanoparticle size, can be seen by eye for each growth step for a collection of silver nanoparticles solutions synthesized with the facile, one-pot seeded growth process developed in this work. The cloudiness of the later growth steps on the right corresponds to the increased scattering and broader plasmonic peaks of larger silver nanoparticles.

FIG. 24 shows a cartoon of the process for self-assembling citrate stabilized silver nanoparticles (AgNP) to a surface using APTES as a positive charge surface functionalization agent.

FIG. 25 shows the effect of absorbing medium (2501, 2502, 2503, 2504) on resonance. There is a redshift and broadening of all peaks, but it the most dramatic for scattering efficiency. Absorption by the particle represents a parasitic loss for many plasmonic particle applications.

FIG. 26 shows a schematic of the mechanisms for plasmonic absorption enhancement in a solar cell. One depicted enhancement mechanism is the plasmonic scatter of light from the incident ray into perpendicular directions with much longer optical path lengths than the depth of the thin-film cell (D), increasing the optical absorption. Additionally, the plasmonic particle can concentrate light in the near field to improve the absorption of optical energy that might otherwise have been lost at the back surface. An ancillary absorption mechanism can be the increase of light trapping through the development of enhanced surface roughness. The primary loss mechanism in this case is the absorption by the particle itself, which can be mitigated by using large particles of primarily scattering metal materials such as silver or aluminum for the core. In this figure, we also show that the vertical location of the particle in the optical absorber material (H) can be adjusted to locate the particle at any position between the two electrode materials in the optical absorber material to achieve the best performance.

FIG. 27 shows the results of “one pot” seeded growth AgNP synthesis. Narrow peak width particles (2701, 2702, 2703, 2704, 2705, 2706, 2707, 2708, 2709) are grown sequentially and the absorbance peak and bandwidth of AgNP synthesized in this method (2910) match well the theoretical expectations (2911).

FIG. 28 shows the absorbance spectra of Ag core —SiO₂ shell nanoparticles. Silica is grown on silver cores using Stöber process. Controllable SiO₂ thickness ranges from 2 to 20 nm.

FIG. 29 shows extraordinary optical interaction. Streamlines of energy are shown flowing around the particles. Plasmonic nanoparticles draw in light from a large area.

FIG. 30 shows the origin of a wavelength dependent response. D=50 nm, in water environment. Plasmonic nanoparticles have a resonance wavelength.

FIG. 31 shows a dielectric shell in a semiconductor medium. 3101 shows the shell in a water medium. 3102 shows the shell in a silicon medium. Two major effects are shown: the first is a reduction in charge carrier trapping, and the second is a strong blue shift in the plasmonic response.

FIG. 32 shows the fabrication procedure for a thin film opto-electronic conversion device. 3201, 3202, and 3203 show the fabrication procedure. 3211 shows the various layers of the thin film opto-electronic conversion device. The opto-electronic conversion device (3211) consists of a substrate (3208), a transparent conducting electrode layer (3207), a first semiconductor optical absorber layer (3206), a second semiconductor optical absorber layer (3205), and a back metal contact electrode (3204). In between layers 3205 and 3206, a thin surface functionalization agent layer (3209) is used to attach a multitude of plasmonic dielectric-coated metal nanoparticles (shown as 3210) to enhance the optical absorption in the semiconductor layers 3205 and 3206. The functionalization agent layer (3209) can be removed after the nanoparticles (3210) are attached to the surface without disturbing the nanoparticles.

FIG. 33 shows plasmonic nanoparticles incorporated in a dye-sensitized solar cell (DSSC) to improve the optical absorption in the weakly absorbed long wavelength region. Plasmonic nanostructures can be positioned at different points in a solar cell.

### DETAILED DESCRIPTION

### Definitions

As used herein, the terms “film” and “layer” will be understood to represent a portion of a stack. They will be understood to cover both a single layer as well as a multilayered structure. As used herein, these terms will be used synonymously and will be considered equivalent.

As used herein, the prefix “nano” means that the item or items that follow the prefix include a dimension on the nanometer scale. As used herein, the term “elongated nanostructure” means an elongated structure having a width or cross-sectional dimension on the nanometer scale. The term “elongated nanostructure” includes nanowires, nanorods, nanopillars, and other similar nanostructures. As used herein, the term “nanoparticle” means a structure having a dimension on the nanometer scale that in some embodiments may be elongated.

The word “conducting” as used herein means electrically conductive.

The “near-field effect” is extra light absorbed around the particle (within a few radii from the surface) above and beyond what would be absorbed if the particle were not present over that whole volume.

By “nanoparticle (NP) displacement” is meant the loss due to the NP taking the place of some of the absorbing layer.

### Introduction

The resonant interaction of light with metal nanoparticles can result in extraordinary optical effects in both the near and far fields. Plasmonics, the study of this interaction, has the potential to enhance performance in a wide range of applications, including sensing, photovoltaics, photocatalysis, biomedical imaging, diagnostics, and treatment. As a scientific discipline, plasmonics enables the extraordinary manipulation of light with sub-wavelength metallic nanostructures through surface plasmons. A surface plasmon is a coherent oscillation of conduction band electrons on the surface of metal structure near a metal-dielectric interface. A dielectric surface acts as a boundary, limiting the oscillation path and confining the electron motion. The coherent oscillations occur because of attractive and repulsive forces of the optical electromagnetic fields (of which the light consists) on the quasi-free charges present in metals.

A surface plasmon exhibits a strong optical interaction between the particle and incident light when the frequency of the incident light coincides with the resonance frequency of the particle. A plasmon response is defined by the existence of a narrow frequency band over which a resonance can occur. This oscillation frequency is dependent on the size of the structure and the materials present. For most metals, this resonance occurs in the ultraviolet portion of the electromagnetic spectrum. However, for nanoscale noble metals, such as gold, silver, or copper, the resonance frequency can be shifted into the range of visible to NIR light.

The plasmonic interaction effect draws light into the particle, providing enhanced optical interaction cross-sections. Non-plasmonic particles that are much smaller than the wavelength of the incident light will exhibit very little optical interaction. The reason is because electromagnetic radiation interacts very weakly with objects smaller than a quarter of the wavelength (λ/4). For a plasmonic particle on resonance, however, a very different interaction pattern can be observed. In this case, the surrounding light field is significantly disrupted, as the particle draws in light from a large area around the particle.

Plasmonic nanostructures have the potential to dramatically improve the performance of thin film photovoltaics by selectively enhancing the absorption of near-band gap light. Low energy, near-infrared photons near the band gap are very weakly absorbed in typical photovoltaic semiconductor materials, but almost all of the energy in these photons is converted into useful electron-hole pairs if absorbed. This mismatch results in an attractive opportunity for improving the performance of thin film solar cells. By creating plasmonic structures tuned to promote the absorption of long wavelength light in the semiconductor, large gains in the overall photovoltaic efficiency could be achieved.

While the resonant interaction of plasmonic nanoparticles offers a promising mechanism by which the absorption near-bandgap light can be strongly enhanced for thin film solar cells, the enhancement comes at a price. The light scattered by the nanoparticle can contribute to enhanced absorption in a photovoltaic material, but the optical absorption by the particle will act as a parasitic loss on the system. This particle absorption loss is an intrinsic property of any metallic material, but the ratio of scattering to absorption can be tuned by adjusting the plasmonic conditions (size, shape, material, and environment), even to the point that the absorption is negligible. The size and material of the plasmonic nanoparticle are two factors that can be readily tuned. Larger particles tend to have larger scattering to absorption ratios, but increased particle size also results in a red-shifted plasmonic response. The plasmonic resonance condition should occur at a photon energy greater than the photovoltaic material bandgap energy, or no plasmonic gains will be observed. Thus, an optimum size is found for each nanoparticle material.

In addition, metal surfaces in contact with, for example, semiconductor, optical absorber materials can act as electron trapping sites, leading to significantly reduced charge collection efficiencies and overall reductions in photovoltaic efficiencies. Given that electron trapping and recombination at metal surfaces within semiconducting material is indeed a problem, then a method for electrically insulating the particles is essential for effective use of plasmonic nanoparticles for solar applications. To accomplish this goal, we propose forming silica shells onto metal nanoparticles.

### Opto-Electronic Conversion Devices

Disclosed herein are thin film opto-electronic conversion devices consisting of a substrate; a pair of conductive layers arranged on the substrate; one or more optical absorbing layers arranged in between the pair of conductive layers. Embedded in the absorbing material, one or more types of dielectric-coated plasmonic metal nanoparticles to enhance the optical absorption in the absorbing layers.

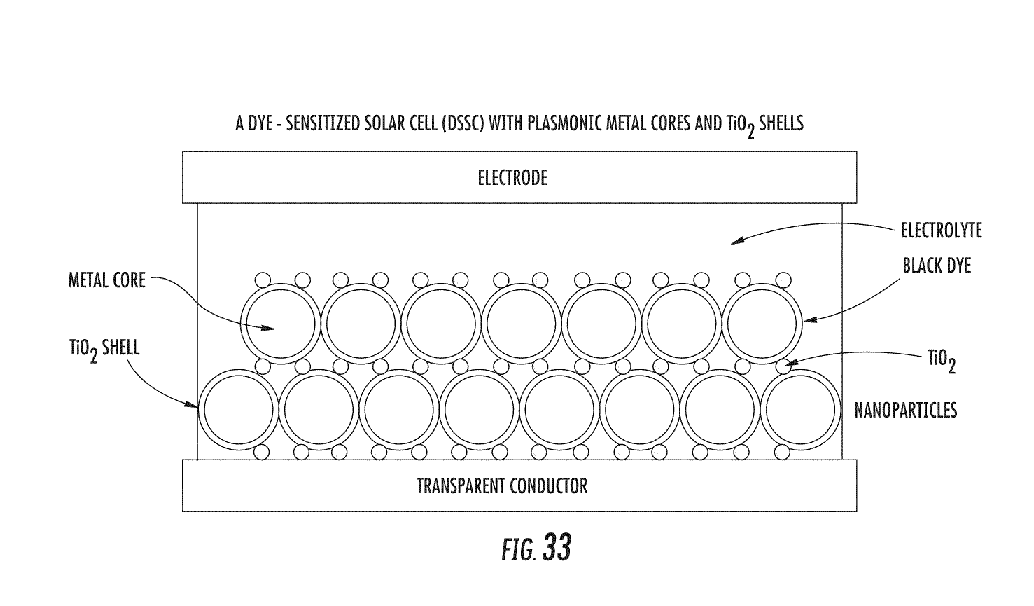

An illustration of this concept can be seen in FIG. 32, which shows a thin film opto-electronic conversion device (3211) consists of a substrate (3208), a transparent conducting electrode layer (3207), a first semiconductor optical absorber layer (3206), a second semiconductor optical absorber layer (3205), and a back metal contact electrode (3204). In between layers 3205 and 3206, a thin surface functionalization agent layer (3209) is used to attach a multitude of plasmonic dielectric-coated metal nanoparticles (shown as 3210) to enhance the optical absorption in the semiconductor layers 3205 and 3206. The functionalization agent layer (3209) can be removed after the nanoparticles (3210) are attached the surface without disturbing the nanoparticles.

The conductive layers can be made from a variety of materials, and can act as an anode and a cathode. At least one of the conductive layers can optionally be a transparent conductive layer such as indium tin oxide (ITO), for example. Other examples include, but are not limited to, graphene, zinc oxide with metal doping, doped tin oxides, cadmium oxides, conductive polymers, or degenerately doped semiconductors.

The optical absorbing layer, in which the plasmonic nanoparticles are optionally embedded, can comprise at least one of a semiconductor material, an organic material, and a photosensitive dye.

The semiconductor material can comprise at least one of silicon, cadmium telluride, copper indium gallium diselenide (CIGS), indium gallium nitride, cadmium sulfide, and gallium arsenide. The semiconducting layers can be fabricated with polycrystalline or amorphous microstructures. Most materials that are deposited using thin film deposition techniques are amorphous (no long range crystalline order). However, by changing the deposition conditions, microcrystalline (crystalline regions with order on the micron scale) silicon can be deposited, which has similar optical properties to crystalline silicon that is grown and sliced from a boule.

When the optical absorbing layer comprises a semiconductor material, the plasmonic nanoparticles can be self-assembled in the optical absorbing layer using a surface functionalization technique. The technique used for nanoparticle deposition can comprise electrostatic self-assembly where charged nanoparticles are attracted to and fixed to an oppositely charged surface, where the particles self-distribute to minimize electrostatic forces between like-charges. The technique used for nanoparticle deposition can also comprise targeted attachment of particles at defined locations using antibodies or synthetic DNA.

The optical absorbing layer can comprise a semiconductor nano/micro-particle colloid material or organic materials present in a solution, sometimes called an ‘ink’, and the plasmonic nanoparticles can be intimately mixed with the semiconductor colloid or the organic material solution and can be printed, sprayed, or otherwise deposited on a surface together with the plasmonic nanoparticles.

When the optical absorbing layer comprises a photosensitive dye, the plasmonic nanoparticles can be sintered with at least one of the conductive layers. The photosensitive dye can be attached to the outside of the dielectric shells, consisting of titanium oxide or titanium nitride, which surround the plasmonic metallic cores. The dielectric coated plasmonic nanoparticles can be sintered together first and then dipped in a dye solution. The sintered nanoparticles form a network of connected particles that can be used for charge collection with at least one of the conductive layers.

The optical absorbing material can have limited absorbing capability, for example, the optical absorbing layer can be characterized by extremely low absorbing efficiencies at longer wavelengths, e.g., the red-NIR portion of the solar spectrum. This low absorption capability can be attributed to the long absorption length of the optical absorbing layer as compared to its thickness.

The optical absorbing material can have a thickness of 0.1, 0.2, 0.3, 0.4, 0.5, 0.6, 0.7, 0.8, 0.9, 1.0, 1.1, 1.2, 1.3, 1.4, 1.5, 1.6, 1.7, 1.8, 1.9, 2.0, 3.0, 4.0, 5.0, 6.0, 7.0, 8.0, 9.0, 10, 11, 12, 13, 14, 15, 16, 17, 18, 19, 20, 25, 30, or 35 um. In one example, the thickness is 10 μm or less. It is noted that thickness depends on the material and its absorption properties. For silicon, for example, the upper range can be 10 μm, but can be thinner, such as 1 μm.

For stronger absorbers, such as CIGS, the total thickness can be as small as 0.25 μm, but could go up to 5 μm. Again, the plasmonic benefit is increased for thinner cells. The plasmonic enhancement can be used to decrease the material usage (and thus provide cost savings at the same cell efficiency).

Furthermore, the optical absorbing material can define a top surface and a bottom surface opposite to the top surface, and the plasmonic nanoparticles can be embedded anywhere in the surface, from the top to the bottom. In one example, the depth of nanoparticles can be from a position touching the top electrode to a position touching the bottom electrode or any location in between within the optical absorber. In other words, they can be embedded near the top of the surface, near the bottom of the surface, or anywhere in between (as shown FIG. 26).

The device can be a photodiode optical detector, a photovoltaic device, or a photoemissive device, for example.

### Plasmonic Nanoparticles

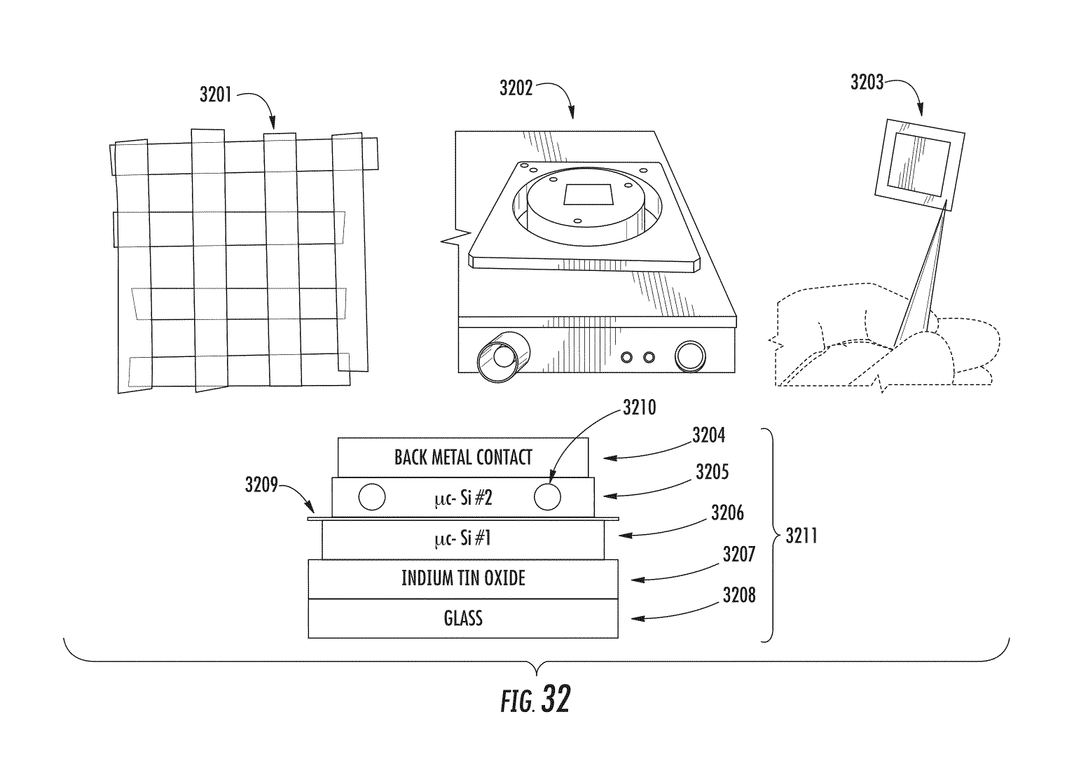

FIG. 31 shows a plasmonic nanoparticle (3101) for use with an optical absorbing material (3205) in an opto-electronic conversion device (3211), comprising: a metal core (3102); and a dielectric layer (3103), wherein the dielectric layer is coated over at least a portion of an outer surface of the metal core, the plasmonic nanoparticles being embedded in the optical absorbing materials (3205) and having at least one characteristic that increases optical absorption of the optical absorbing material.

By “increasing optical absorption” is meant a 10, 20, 30, 40, 50, 60, 70, 80, 90, 100%, or more increase in the absorption of light when compared to the amount absorbed using only the optical absorbing material. The characteristics that increase optical absorption when the dielectric coated plasmonic nanoparticles are used can be tuned by changing the material they are made of, the shape, the dimensions, the distance from each other as they are embedded inside the absorbing material, or a combination thereof. For example, one or more wavelengths at which the optical resonance occurs can be tuned by changing one or more characteristics of the metal core and the dielectric layer. The optical resonance can occur at one or more wavelengths in a region of the solar spectrum that are poorly absorbed by the optical absorbing material. For example, the optical resonance can occur at one or more wavelengths in approximately a red to near-infrared region of the solar spectrum. In another example, the optical resonance can occur at one or more wavelengths shorter than the band-gap wavelength, or in other words, energies greater than the band-gap energy. In another example, the thickness of the dielectric coating can be tuned to minimize the problem of the charge carrier trapping effect caused by the metal core being embedded in the optical absorbing layer.

The plasmonic nanoparticles can increase the optical absorption of the optical absorbing material by increasing the optical pathway of incident light through the optical absorbing material. Alternatively or additionally, the plasmonic nanoparticles can increase the optical absorption of the optical absorbing material by enhancing a direct near-field concentration of incident light. In some cases—as in an extremely thin layer of a strong absorber—near-field concentration of light can result in increased absorption in the absorber layer which otherwise can only be absorbed at the back surface or reflected back out. The particle concentration increases the local absorption, which in the limit of incomplete absorption can yield a net gain. Optionally, the plasmonic nanoparticle can increase the surface roughness and optical trapping effect of the optical absorbing material.

### Metal Core

The metal core of the plasmonic nanoparticle can be formed from at least one of aluminum, copper, gold, iron, silver, titanium, nickel, and zinc. The metal core can have a characteristic length of 10, 20, 30, 40, 50, 60, 70, 80, 90, 100, 110, 120, 130, 140, 150, 160, 170, 180, 190, 200, 210, 220, 230, 240, 250, 260, 270, 280, 290, 300, 350, 400, 450, 500, or more nm. In one example, the metal core has a characteristic length of less than about 300 nm.

The colloidal synthesis of metallic nanoparticles has a wide range of advantages for the creation of plasmonic nanostructures. Metal nanoparticle synthesis is inexpensive, achievable with common laboratory equipment and chemicals, and can be used to fabricate a wide range of metal nanostructures. These particles can be stabilized in aqueous or organic solvents for time periods measured in centuries. Various reducing agents can be used to synthesize metal nanoparticles, including environmentally-friendly, biologically-derived reducing agents. Furthermore, unlike metal particles deposited by sputtering, the energy requirements are very low, as no vacuum conditions or high temperature annealing is necessary to achieve desired nanoparticle sizes. Nanoparticles can be applied on solid substrates using spray techniques, drop-casting or self-assembly, although obtaining uniform, evenly spaced nanoparticle depositions can be challenging. Lithographic approaches, such as electron-beam (e-beam) deposition, are the gold standard methods for creating designed nanostructures. Unfortunately, however, the cost and time constraints on lithography are fundamentally limiting, meaning that lithographic nanostructure nanoparticle fabrication cannot be currently be accomplished on wide enough scale for medical or solar applications.

One of the primary advantages of colloidally synthesized metal nanoparticles is the degree of control that can be obtained over the size and shape of the particle. For example, nanorods, branched structures, discs, triangular prisms, wires, spheres, and ovoids are among the many shapes of plasmonic metal nanoparticles synthesized to date. The size of particles synthesized using wet-chemistry methods can range from a nanometer to several hundred nanometers. Furthermore, shell coatings with homogenous thicknesses can be grown on top of the nanoparticle, even leading to two layer structures and more. The shell materials can be metal or dielectric materials. Examples of forming plasmonic nanoparticles can be found in the Examples section.

When metal nanoparticles are embedded in most optical absorbing media, the plasmonic resonance exhibits a strong red-shift relative to the resonance in water, often to a wavelength beyond the band-gap or in other words to energies lower than the band-gap energy (which is then useless for increasing the absorption of the optical absorbing layer. This problem can be overcome with a thin dielectric shell, or also by using non-typical plasmonic metal materials (such as aluminum).

### Dielectric Layer

The dielectric layer of the plasmonic nanoparticle can be formed from at least one of silicon dioxide, silicon nitride, diamond-like carbon, titanium dioxide, titanium nitride, iron oxide, zinc oxide, aluminum oxide, copper oxide, and aluminum nitride. The dielectric layer can have a thickness of 0.1, 0.2, 0.3, 0.4, 0.5, 0.6, 0.7, 0.8, 0.9 1, 2, 3, 4, 5, 10, 15, 20, 25, 30, 35, 40, 45, or 50 nm, or any amount smaller, lower, or in between these thicknesses. In one example, the thickness is less than about 50 nm. When the dielectric layer is formed from silicon dioxide (SiO2), the dielectric layer can also be referred to as the “silica shell.” Dielectric shells can be formed onto metal nanoparticles. Dielectric shells can have a profound impact on the plasmon resonance condition, which can be profitably used for photovoltaic applications. A dielectric shell on a metal nanoparticle changes the local environment. For example, for a metal nanoparticle in water (n≈1.33), the presence of a silica shell (n≈1.5) will result in a weak red-shift in the plasmonic response. However, the resonance of a metal nanoparticle embedded in an optical absorbing layer with large index of refraction, n, (for example, a microcrystalline silicon medium with n≈4), will strongly red-shift. A silica shell on a metal nanoparticle embedded in medium with high index of refraction (n≈4), advantageously, has a very strong blue-shift effect on the plasmon resonance. A blue shifted response can be used to employ larger particles at the same resonance wavelength, leading to larger scattering efficiencies and lower absorption losses (the absorption of smaller metal nanoparticles is very large compared to their scattering ability). In one example, dimethylamine (DMA) can be used to aid in the relatively rapid formation of silica shells on silver nanoparticles. Further methods for synthesis of silica shells on silver nanoparticles are disclosed in the Examples section.

The dielectric layer of the plasmonic nanoparticle can reduce a charge carrier trapping effect caused by the metal core being embedded in the optical absorbing material. This charge carrier trapping can be a very significant recombination center, and can dramatically reduce the efficiency of charge collection and conversion if not addressed. This characteristic can be optimized by changing the thickness of the dielectric layer.

### Methods

Further disclosed herein is a method of manufacturing a thin film opto-electronic conversion device, comprising: providing a substrate 3208; forming a pair of optical absorbing layer 3205, 3506 arranged on the substrate; forming at least one optical absorption enhancement between the pair of conductive layers by embedding one or more plasmonic nanoparticles 3210 in the optical absorbing layer, wherein the plasmonic nanoparticles have at least one characteristic that increases optical absorption of the optical absorbing layer. The substrate can be, for example, glass, or flexible plastic, or metal foil.

Also disclosed herein is a method of manufacturing one or more plasmonic nanoparticles, comprising: forming a metal core; and coating a dielectric layer over at least a portion of an outer surface of the metal core, wherein the plasmonic nanoparticles have at least one characteristic that increases optical absorption of an optical absorbing material when embedded therein.

In one example, the optical absorbing layer can comprise a semiconductor material formed through a deposition process, the method further comprising self-assembling the plasmonic nanoparticles in the optical absorbing layer using a surface functionalization technique. The optical absorbing layer can also comprise a semiconductor material or an organic material formed through a printing process, the method further comprising mixing the plasmonic nanoparticles with the semiconductor material or the organic material prior to forming the optical absorbing layer.

The narrow size distribution plasmonic metal core can be formed through a process including an initial step using a strong reducing agent to form metal seeds. The metal seeds can be 0.1, 0.2, 0.3, 0.4, 0.5, 0.6, 0.7, 0.8, 0.9, 1.0, 2.0, 3.0, 4.0, 5.0, 6.0, 7.0, 8.0, 9.0, 10.0, 11.0, 12.0, 13.0, 14.0, 15.0, or more, less, or any amount in between. For instance, the metal seeds can be 0.5 to 10 nm. The metal seeds can then be grown in stages using a weaker reducing agent using thermal control to minimize the formation of new nanoparticle seeds. The steps following the initial seed reduction step are conducted to minimize creation of new seeds during particle growth through thermal (kinetic) control.

Examples of strong reducing agents are sodium borohydride, potassium borohydride, lithium aluminum hydride, diborane, hydrazine, or hydrogen. Examples of weak reducing agents are sodium citrate, ascorbic acid, glucose, dimethylformamide, alcohol, polyols, ethylene glycol, or oleylamine

In one example, to fully utilize nanoparticles in planar configurations, it is of value to assemble nanoparticles in a uniform layer on the surface with uniform spacing between the particles. Evenly distributed two-dimensional arrays of nanoparticles on a surface could be useful for refractive index sensing, plasmonic nanoablation, and photovoltaic applications. The self-assembly of nanoparticles can be accomplished by functionalizing the surface such that the nanoparticles are electrostatically bound to the surface. The procedure for self-assembly thus depends on the charge of the nanoparticles. Sodium citrate ions induce a negative charge on the surface of the nanoparticles and are often used to stabilize colloidal solutions of nanoparticles through electrostatic repulsion. Monolayers of polyvinylpyridine (PVP) and aminopropyltriethoxysilane (APTES), among others, can be used to generate a positively charged ‘functionalized’ surface. Nanoparticles stabilized with CTAB, on the other hand, are positively charged, meaning that a negatively charged surface functionalizing agent must be used. The mechanism for the creation of self-assembled monolayers (SAMs) is the creation of a charged monolayer surface coating, followed by the immersion of stabilized nanoparticles with the opposite charge. The nanoparticles can stick to the surface, but there is an energy barrier to agglomeration because of the like charges on the nanoparticles. The particles will self-organize on the surface according to these influences. Self-assembly using synthetic DNA or targeted molecules such as antibodies are other methods by which controllable nanoparticle deposition could be achieved.

By way of non-limiting illustration, examples of certain embodiments of the present disclosure are included below.

### EXAMPLES

### Example 1

### Nanoparticle Synthesis

Disclosed herein are synthesis procedures for producing a diverse range of high quality nanoparticles using wet chemistry procedures. The characterization of the synthesized nanoparticles, including UV-Vis-NIR spectroscopy, scanning transmission electron microscopy (STEM), and energy-dispersive x-ray spectroscopy (EDS) are also discussed.

### Methods

Beakers were washed with soap and water, then soaked in aqua regia to remove metal ions and other contaminants and residues. The beakers were triple-rinsed with distilled water, and then again triple-rinsed with ultrapure water. Ultrapure water system (Elga Option-Q 15) produced water with a resistivity of 18.2 MΩ·cm. Ultrapure water was used as a solvent for all aqueous reactions, while absolute ethanol (Fisher) was used for various other reactions such as the Stöber process for growing silica particles and shells.

All chemicals were used without further purification. Silver nitrate (AgNO₃), which has a molecular weight (MW) of 169.87 g/mol, was purchased from Acros (99%, Reagent grade). Chloroauric acid (HAuCl₄×3H₂O) was used a gold ion source. The chloroauric acid was sourced from Acros (Reagent Grade, 99%). Trisodium citrate dihydrate (Na₃C₆H₅O₇, MW=294.1) was purchased from Sigma-Aldrich (ACS Reagent Grade, >99%). Cetyl trimethyl ammonium bromide (CTAB, Fluka, 96%), tetraethylorthosilicate (TEOS, TCI, >96%), and aminopropyltriethoxysilane (APTES, Sigma-Aldrich, >98%). Sodium borohydride (Fisher Scientific) was stored in a dessicator to minimize water absorption.

### Sphere Synthesis

Research by Turkevich et al. in 1951 identified the citrate reduction synthesis method for creating gold nanoparticles. This reaction remains one of the simplest and most straightforward methods for synthesizing metal nanoparticles (J. Turkevich, P. C. Stevenson and J. Hillier. A study of the nucleation and growth processes in the synthesis of colloidal gold. Discussions of the Faraday Society, 55 (1951)) but various other advances, such as the reverse micelle method, have also been used to synthesize gold particles in highly monodispersed solutions (Pileni, M. P. Nanosized Particles made in Colloidal Assemblies. Langmuir, 13 (1997)). Disclosed herein are extended results and characterization of noble metal spheres synthesized using a modified Turkevich process. The focus is on the size distribution of nanoparticle samples, which were evaluated through plasmonic peak full-width half-max measurements and electron microscopy.

Size Control with Gold Nanospheres

A recently published kinetic nanoparticle size control offers unprecedented control over nanoparticle size in a one-pot synthesis technique using sodium citrate as a reducing agent (N. G. Bastus, J. Comenge and V. Puntes. Kinetically Controlled Seeded Growth Synthesis of Citrate-Stabilized Gold Nanoparticles of up to 200 nm: Size Focusing versus Ostwald Ripening. Langmuir, 27 (2011)). The method relies on controlling the competitive mechanisms associated with polydispersity in nanoparticle growth. One of the largest sources of different nanoparticle sizes in solution occurs due to the continuing reduction of gold ions in solution to nanoparticles, which creates a variation in nanoparticle size because the growth on each nanoparticle in solution is similar, so nanoseeds that form later result in smaller final nanoparticles. By controlling the energy available to the reaction processes through a slight reduction of the synthesis temperature, the creation of new seeds is rendered energetically unfavorable. If new seed formation can be reduced, then holding the colloidal synthesis solution at temperature can result in nanoparticle size focusing through Ostwald ripening, where larger nanoparticles approach monodispersity as the smaller particles dissolve and their constituent gold ions are integrated into larger particles. To evaluate the potential of this technique for nanoparticle growth, a range of particle sizes using a kinetic size control approach was evaluated.

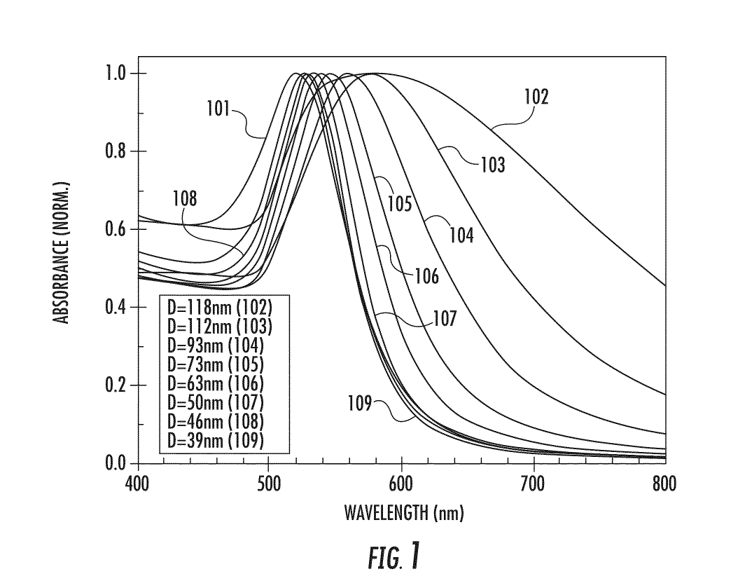

FIG. 1 shows the absorbance spectra for a set of gold nanospheres synthesized using the seeded growth method. The seeded growth technique yields repeatable gold nanoparticles with a relatively narrow size distribution. These results were obtained using a process similar to that described in Bastus, 2011. For each incremental growth step, the plasmonic resonance peak, represented here as a maximum in the absorbance, red-shifts, indicating a larger nanoparticle than the previous growth stage. The only exception to this trend is in the first step of growth from the seeds, where a significant narrowing in the resonance peak is also observed. From this result, it was observed that the size focusing is especially pronounced in this first growth stage.

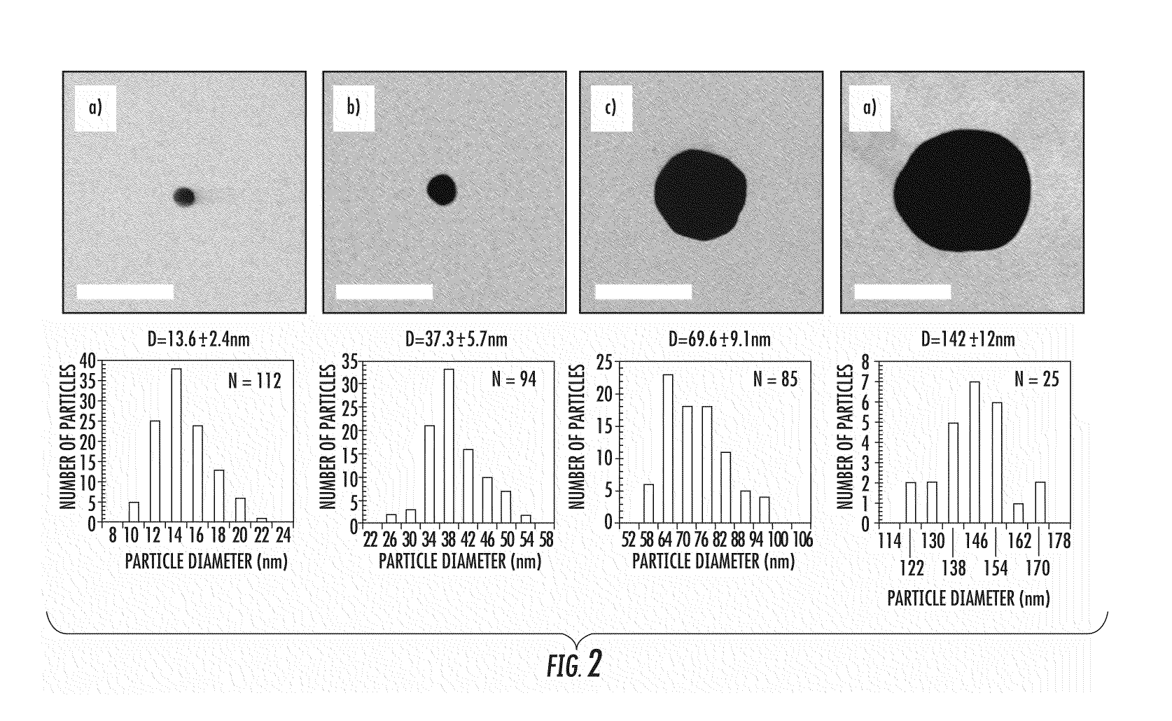

FIG. 2 shows representative images and histograms of the measured particles for four of the nanoparticle samples synthesized with kinetic control. The synthesized nanoparticles were characterized with a field-emission scanning transmission electron microscope (Hitachi S-5500). The particles were analyzed using particle measurement tools in the microscopy software suite ImageJ. Briefly, the intensity of the particles was adjusted with a thresholding technique, and then the image was transformed into binary bit-depth. Care was taken to only count isolated particles that were well-resolved in the images. The results for each of the syntheses are tabulated in Table 1. The empirically calculated gold nanoparticle diameters were found according to Equation 1, which was found from a numerical fit of ten separate nanoparticle synthesis, growth and characterization studies. The equation used for the empirical fit is taken from Khlebtsov, N. G. Determination of Size and Concentration of Gold Nanoparticles from Extinction Spectra. Analytical Chemistry, 80 (2008).

$$D = \{ \begin{matrix}3 + ( 7.5 \times {10}^{- 5} ) {( {λ}_{max} - 500 )}^{4} , for {λ}_{max} < 523 \\ 16.67 ( \sqrt{{λ}_{max} - 40} - 1 ) , for {λ}_{max} \geq 523\end{matrix} \qquad ( 1 )$$

Equation (1) is a fit of the relationship between the nanoparticle size and plasmon resonance peak, where the nanoparticle size was measured with electron microscopy and the plasmon peak was determined using a spectrometer. The nanoparticle size can also be iteratively predicted from the plasmon peak using Mie theory by varying the diameter until the correct resonance peak value is found. The Mie theory size estimates are calculated using the constants of Johnson and Christy and fit to the peak position of the experimental spectra.

TABLE 1
Synthesized gold nanoparticle properties

| | Growth Step | | | | | | | | |
|---|---|---|---|---|---|---|---|---|---|
| | 1 | 2 | 3 | 4 | 5 | 6 | 7 | 8 | 9 |
| Resonance Peak (nm) | 521 | 530 | 530 | 530 | 530 | 530 | 530 | 530 | 530 |
| Empirical Diameter (nm) | 16 | 36 | 46 | 50 | 64 | 74 | 92 | 112 | 118 |
| Mie Diameter (nm) | 14 | 40 | 50 | 54 | 68 | 76 | 90 | 108 | 112 |
| Measured Diameter (nm) | 13.6 ± 2.4 | — | 37.2 ± 5.7 | — | — | 70 ± 9.1 | — | — | 142 ± 12 |

Improved Monodispersity with Gold Nanospheres

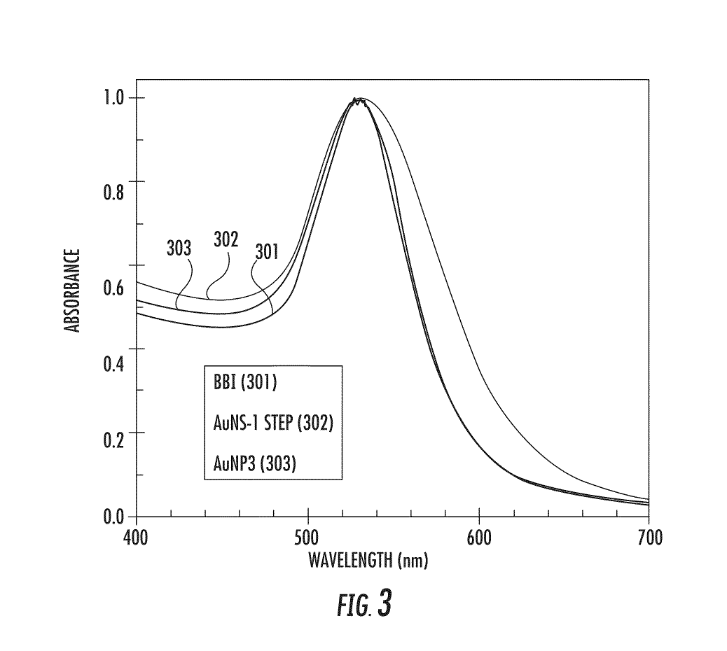

As can be seen from the widths of the peaks in FIG. 3, the method approaches the narrow size distribution of commercially purchased gold nanoparticles. The peak shifts slightly for every different particle size around the median, so the presence of multiple particle sizes in a nanoparticle sample results in a broadening of the plasmon peak.

Table 2 shows the measured and predicted properties for each of the nanoparticles shown in FIG. 3. It was also found that the stepped growth particles had improved shape and reduced ellipticity in comparison with the nanoparticles directly formed in one step.

TABLE 2
A comparison of synthesized gold nanoparticle properties.
The nanospheres denoted BBI are purchased from a commercial
source. The other nanoparticles are synthesized in-
house with either a 1 or 3 step process.

| Nanoparticles | BBI | 1-Step | 3-Step |
|---|---|---|---|
| Resonance (nm) | 530 | 532 | 531 |
| FWHM (nm) | 70 | 108 | 70 |
| Diameter (nm, Emp.) | 43 | 48 | 46 |
| Diameter (nm, MieJC) | 48 | 52 | 50 |

### Advanced Methods for Size Control of Silver Nanospheres

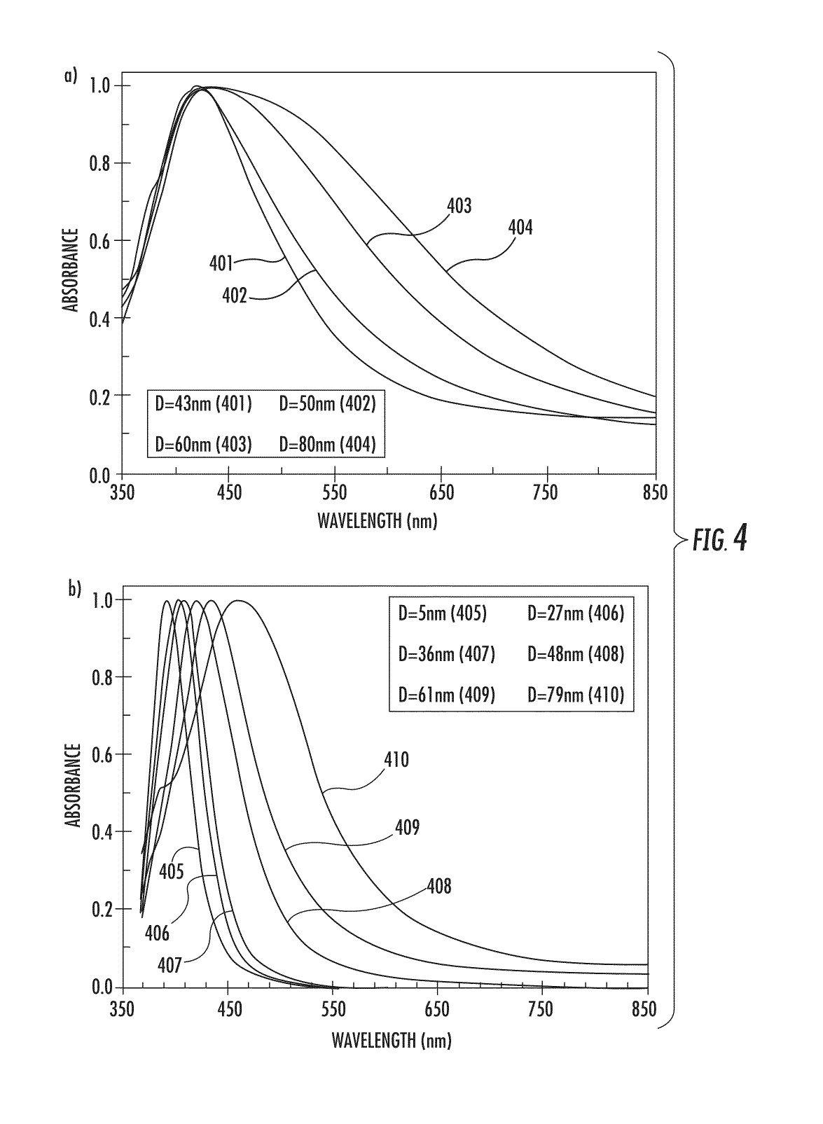

Building on previous efforts for controlled growth of silver nanoparticles, a new method for extremely fine control of the nanoparticle size was developed. By applying the size-focusing approach to extremely fine nanoparticle seeds generated using the strong reducing agent sodium borohydride, extremely narrow size distribution sets of nanoparticles were created. These particles could then be grown while maintaining the narrow size distribution properties (FIG. 4(b)).

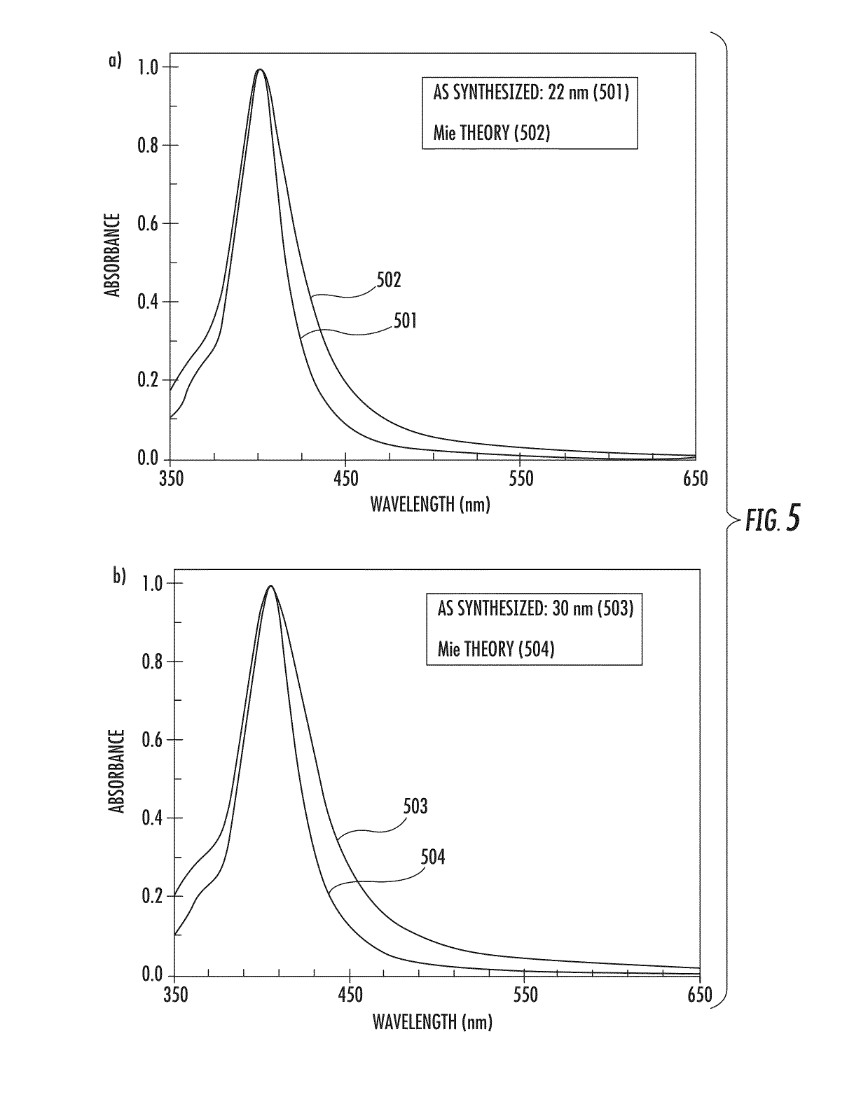

The UV-Vis-NIR spectra are shown in FIG. 5 for two narrow size distribution nanoparticle colloids synthesized with the seeded growth method. The simulations are shown for comparison for a single nanoparticle size, revealing the near-monodispersity of samples prepared using this method.

Another interesting feature of the nanoparticle growth process was the significant narrowing in the plasmon peak during the first growth stage. This can be seen for nanoparticles prepared using both sodium citrate and sodium borohydride as an initial reducing agent. This reduction in the peak width corresponds to a ripening process where smaller nanoparticles dissolve and the added silver in solution evens out the nanoparticle sizes.

### Nanorod Synthesis

With recent developments in non-spherical gold nanoparticle synthesis, the optical and plasmonic properties of a variety of new asymmetrical ‘broken symmetry’ geometries, such as nanorods, prisms, and stars, have been investigated (K. L. Kelly, E. Coronado, L. L. Zhao and G. C. Schatz. The Optical Properties of Metal Nanoparticles: The Influence of Size, Shape, and Dielectric Environment. Journal of Physical Chemistry B, 107 (2003); H. Wang, Y. Wu, B. Lassiter, C. L. Nehl, J. H. Hafner, P. Nordlander and N. J. Halas. Symmetry breaking in individual plasmonic nanoparticles. Proceedings of the National Academy of Sciences, 103 (2006)). Asymmetrical nanostructures typically can provide much larger extinctions and near-field enhancements than spherical nanoparticles for comparable resonance frequencies and volumes. In addition, non-spherical particles can also provide access to polarization and orientation effects not available in spherical particles. Gold nanorods have especially intense interaction with NIR light. Unlike spheres, nanorods exhibit two resonances: a transverse and larger longitudinal resonance at longer wavelengths, depending strongly on both the diameter and the aspect ratio. By changing the geometry of the rods, the central wavelength of their longitudinal resonances can be tuned from visible to near-infrared wavelengths. Furthermore, by controlling the nanorod diameter and geometry, the scattering to absorption ratio and angular distribution of scattering can be adjusted at a given plasmonic resonance wavelength.

### Gold Nanorod Synthesis Protocol

Gold nanorods are attractive for use in many plasmonic applications because of their stability, strong optical response, and biological compatibility. There are several different procedures for fabricating AuNRs. One is the two-step process, discussed herein. The first step involves the reduction of gold in solution into small gold ‘seeds’, while the second step consists of the soft template-directed growth of a nanorod from the seeds. It has previously been shown that AuNR fabricated in this manner are single-crystal domains. The size, aspect ratio and longitudinal plasmon resonance peak can all be tuned during the growth stage by adjusting the ratios of the constituent chemical solutions.

There are several key ‘rules of thumb’ for synthesizing gold nanorods. First, the nanorod aspect ratio is dependent on the AgNO₃ concentration. A lower concentration of silver nitrate (AgNO₃) will lead to shorter rods. Secondly, the total nanorod volume is strongly dependent on the amount of seeds added to the growth solution. Reducing the seed concentration will lead to fewer, larger rods as the gold in solution will be exhausted in the nanorod growth phase. The nanorod shape is weakly dependent on ascorbic acid concentration. The presented nanorod synthesis procedure will give small, primarily absorbing nanorods (roughly 13×43 nm), with an 87% yield of nanorods with a longitudinal resonance at ˜800 nm. Silver nanorods can also be obtained using a similar procedure.

### Silica Shell Synthesis

Concentric nanoshell structures can be extremely interesting for plasmonic study. Silica-core, gold shell particles were one of the first structures designed with a peak in the near-infrared. Silica particles can be synthesized with a Stöber process, while a modified Stöber process can be used to grow silica shells on metal cores.

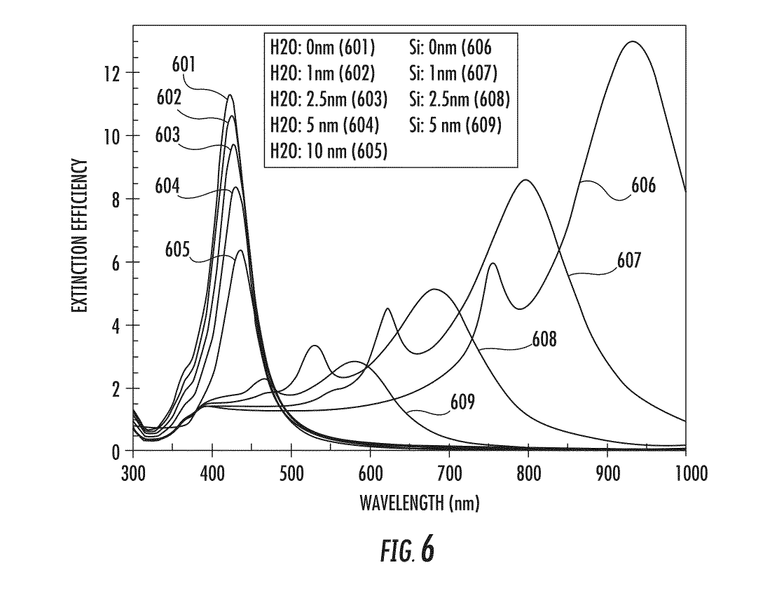

It was hypothesized that metal surfaces within solar absorber materials can act as electron trapping sites. If this is indeed the case, then a method for electrically insulating the particles is needed. To accomplish this goal, silica shells were formed onto metal nanoparticles. Silica shells can have a profound impact on the plasmon resonance condition, which can be profitably used for photovoltaic applications. A silica shell on a metal nanoparticle changes the local environment. For a metal nanoparticle in water (n˜1.33), the presence of a silica shell (n˜1.5) will result in a weak red-shift in the plasmonic response. A silica shell on a metal nanoparticle embedded in a microcrystalline silicon medium (n˜4), however, has a very strong blue-shift effect on the plasmon resonance. Simulated spectral results are shown in FIG. 6, illustrating these two cases. A blue shifted response can be used to employ larger particles at the same resonance wavelength, leading to larger scattering efficiencies and lower absorption losses.

Several different methods were evaluated for silica shell growth. Procedures for coating metal nanoparticles with a silica shell generally consist of two primary processes. First, there must be a replacement of the existing surfactant or stabilization ions or molecules. In this first step, a silicon-containing material should be attached to the surface. Chemically, this can be accomplished using aminopropyltriethylsilane (APTES) or tetraetylorthosilicate (TEOS). When using APTES, only a monolayer can be grown effectively without causing aggregation, so extended intermediate growth must be taken with activated silica. The next step involves the growth of the silica shell in a Stöber process, typically in an ethanol-based solution using TEOS. The initial experiments with both techniques found that the TEOS-based initial coating with subsequent growth to provide the most consistent and useful results with a rapid and simple process, so all further silica shell growth procedures were completed in this manner.

However, the TEOS growth process proceeds very slowly at room temperature, taking up to a week of growth to obtain shells of reasonable thickness. Furthermore, this process was influenced by the surrounding temperature and environment. For this reason, catalysts to increase reaction speed were investigated. While both acidic and basic environments can aid in silica-shell deposition, challenges can arise in the form of silica particle precipitation. Ammonium (NH₄) has been used to catalyze the silica coating of gold nanoparticles, but silver nanoparticles are unstable in the presence of ammonium.

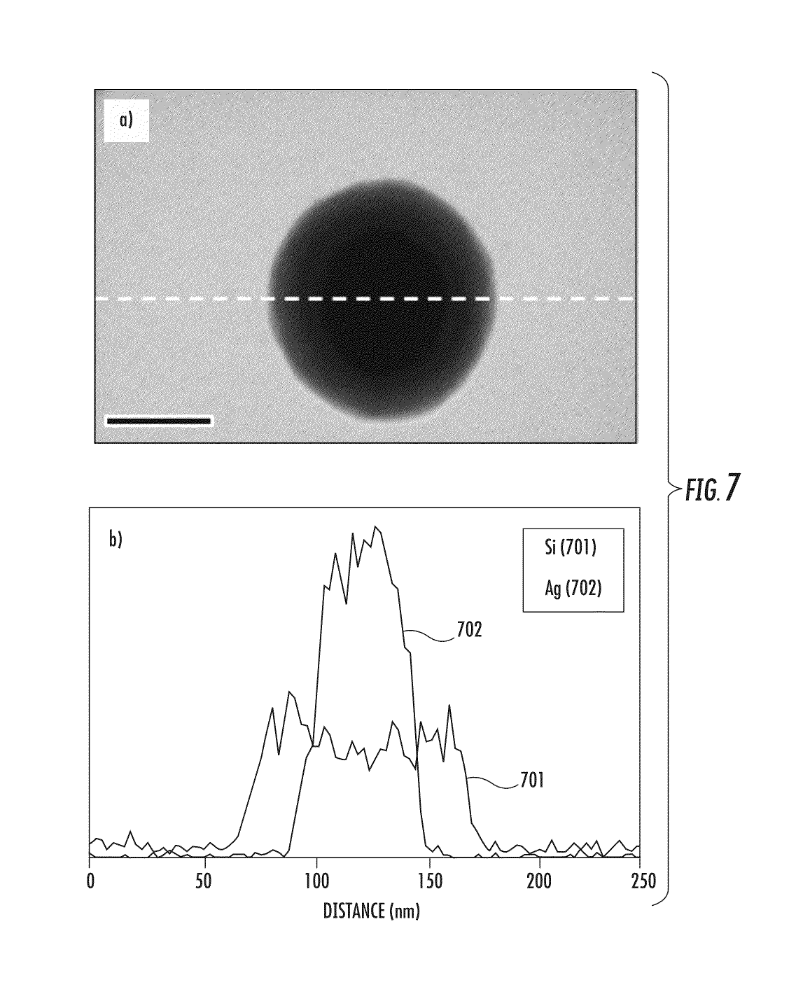

Dimethylamine (DMA) was used to aid in the relatively rapid formation of silica shells on silver nanoparticles, as suggested by Kobayashi et al. (Y. Kobayashi, H. Katakami, E. Mine, D. Nagao, M. Konno, and L. M. Liz-Marzan. Silica coating of silver nanoparticles using a modified Stoeber method. Journal of Colloid and Interface Science, 283, dx.doi.org/10.1016/j.jcis.2004.08.184 (2005), 392-396.) This procedure results in coated nanospheres within five hours (D. Mongin, V. Juve, P. Maioli, A. Crut, N. Del Fatti, F. Vallee, A. Sanchez-Iglesias, I. Pastoriza-Santos, and L. M. Liz-Marzan. Acoustic Vibrations of Metal-Dielectric Core-Shell Nanoparticles. Nano Letters, 11 (2011), 3016-3021.) FIG. 7 shows a 75 nm silver particle with a silica shell fabricated with this procedure.

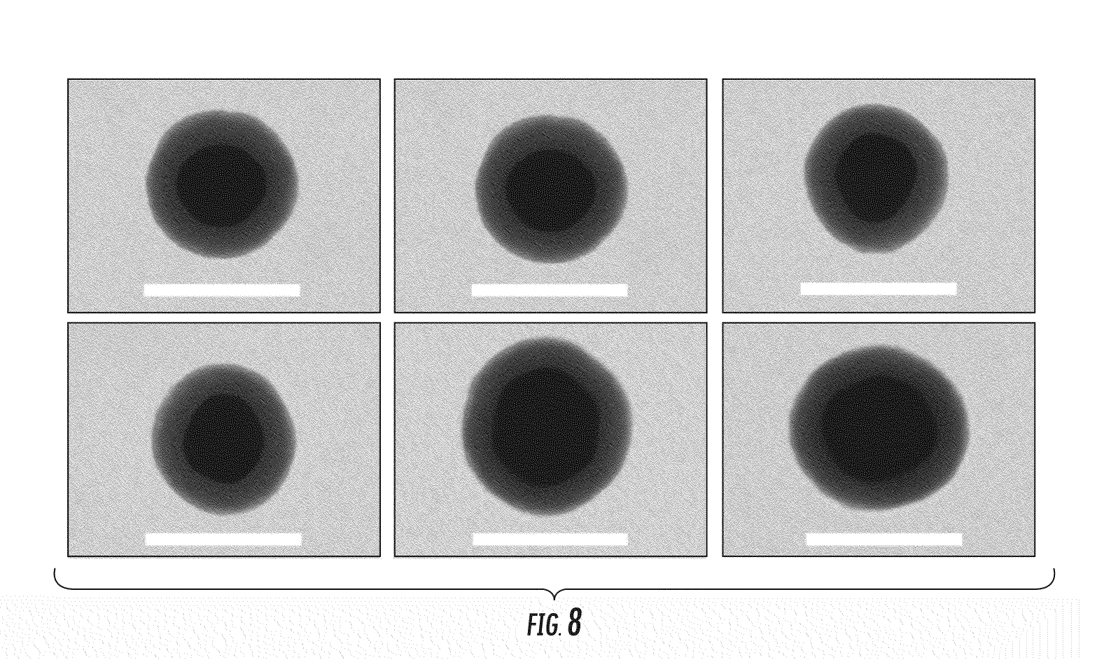

FIG. 8 shows several representative STEM images of silica shells on silver cores. For this characterized sample, the shell thickness was found to be extremely consistent across various particles with a thickness of 19.5±1.2 nm, despite a relatively wide distribution of metal core sizes.

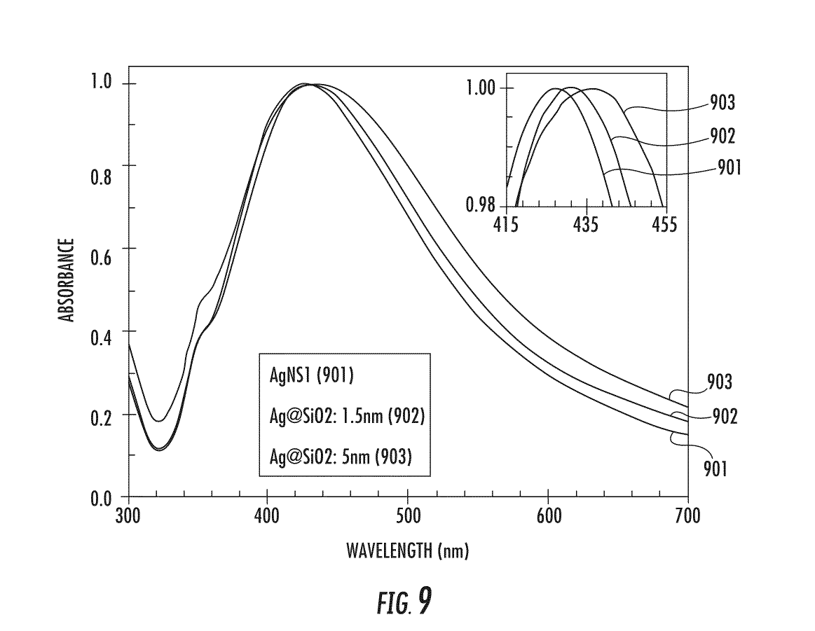

It is necessary to control the thickness of the shell to obtain shell behaviors while maintaining enhanced near-field properties. Increased concentrations of either TEOS or DMA led to thicker coatings, but the thickness can also be effectively controlled by adjusting the initial concentration of nanoparticles. Prior results in the literature indicate that 2 nm thickness of SiO₂ is sufficient to greatly reduce conductivity or electron interaction with metal surfaces. Silica coatings as thin as 2 nm have previously been fabricated on gold nanoparticles (L. M. Liz-Marzan, M. Giersig, and P. Mulvaney. Synthesis of Nanosized Gold-Silica Core-Shell Particles. Langmuir, 12 (1996), 4329-4335). However, it was found that an increase in nanoparticle concentration was necessary to repeatably synthesize thin shells on silver cores. Small silver nanoparticles with thin shell structures were unstable in an 80% ethanol solution. Thin shells were grown using a modified procedure with an increased concentration of up to 40% nanoparticle solution in ethanol, compared with only 20% in the previously published procedure. The rapid formation of a thick silica shell stabilizes the nanoparticles, but higher aqueous nanoparticle colloid concentrations lead to improved stability. A range of thicknesses were synthesized on silver spheres to demonstrate control of the thickness. A small set of the nanoparticles synthesized are compared in FIG. 9.

### Self-Assembled Monolayers of Metal Nanoparticles

To fully utilize nanoparticles in planar configurations, it is of value to assemble nanoparticles in a uniform layer on the surface with uniform spacing between the particles. Evenly distributed two-dimensional arrays of nanoparticles on a surface can be useful for refractive index sensing, plasmonic nanoablation, and photovoltaic applications. The self-assembly of nanoparticles can be accomplished by functionalizing the surface such that the nanoparticles are electrostatically bound to the surface. The procedure for self-assembly thus depends on the charge of the nanoparticles. Sodium citrate ions induce a negative charge on the surface of the nanoparticles and are often used to stabilize colloidal solutions of nanoparticles through electrostatic repulsion. Monolayers of polyvinylpyridine (PVP) and aminopropyltriethoxysilane (APTES), among others, can be used to generate a positively charged ‘functionalized’ surface. Nanoparticles stabilized with CTAB, on the other hand, are positively charged, meaning that a negatively charged surface functionalizing agent must be used. The mechanism for the creation of self-assembled monolayers (SAMs) is the creation of a charged monolayer surface coating, followed by the immersion of stabilized nanoparticles with the opposite charge. The nanoparticles will stick to the surface, but there is an energy barrier to agglomeration because of the like charges on the nanoparticles. The particles self-organize on the surface according to these influences.

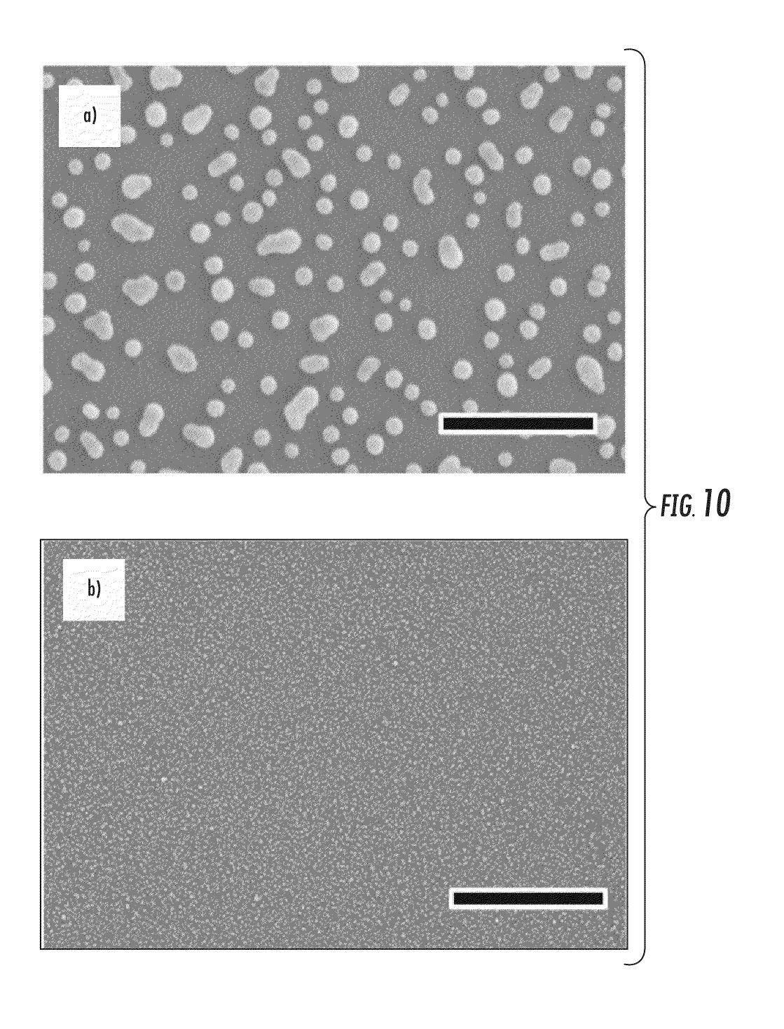

Many different tests were performed to identify conditions by which homogeneous monolayers of various nanoparticle sizes in both gold and silver could be formed across a 1″×1″ area. These conditions are found to be general for substrate materials including silicon and glass, and previous research has described the method as universal. FIG. 10 shows the regularity of spacing and high nanoparticle densities that can be achieved with surface functionalization. It was found that the most important variables for effective SAM growth are surface cleanliness, nanoparticle concentration and timing

### Other Particles and Materials

### Silica Spheres

Silica spheres were synthesized with a modified Stöber process (W. Stoeber, A. Fink, and E. Bohn. Controlled Growth of Monodisperse Silica Spheres in the Micron Size Range. Journal of Colloid and Interface Science, 26 (1968), 62-69). Briefly, TEOS was added to a mixture of ethanol and water under stirring. Subsequently, ammonia was added to this mixture to catalyze the formation of silica nanoparticles in solution. Over a period of several hours, the reaction gradually became pearlescent, and then finally a milky white. Silica nanoparticles were formulated that were ˜100 nm in diameter, but the overall size could be adjusted by varying the ratio of the reagents. These particles were synthesized to provide a non-plasmonic source of scattering and roughness for comparison with plasmonic particles for solar applications.

### Silver Triangles

Triangular prism nanoparticles are very attractive because of thickness, strong plasmonic response, strong near-field response, insensitivity to incident polarization, and tunability. First efforts were made towards the synthesis and characterization of silver nanoprisms. The particles were synthesized using a modified procedure from the literature according to the protocol listed below. Investigations into the sensitivity of the reactions towards various chemical reagents were carried out, showing that the reaction was strongly dependent on the concentration of silver seeds. Reduced amounts of silver seeds led to larger prisms.

### Spectrometer System Development and Calibration

Significant efforts in nanoparticle synthesis require a great deal of characterization analysis. The quickest and easiest way to evaluate nanoparticles during and after synthesis is through the use of UV-Vis-NIR Spectrophotometry. Spectrophotometry is accomplished by collimated light is sent through a sample, transmission at a range of wavelengths is evaluated and finally the differences between a test sample and a control are determined. The strong optical properties of plasmonic metal nanoparticles can lead to pronounced spectral peaks even at low concentrations when measured with spectrometric methods. This technique is extremely useful for rapidly measuring plasmonic extinction spectra using the absorbance peak positions, and can also be used to evaluate nanoparticle polydispersity through absorption peak widths.

To enable testing during synthesis and to allow for vastly increased testing of various synthesis samples, a nanoparticle absorbance measurement system was developed using available components, including a grating-based wavelength splitter (Andor 163), Peltier-cooled semiconductor camera, tungsten lamp, collimation optics, neutral density filters, and various optical mounting components. The spectrometer is equipped with a 100 μm×3 mm slit that acts as a spatial filter, rejecting stray scattered light. The light from the light source was collimated with either a 50 mm lens (with a focal length of 40 mm), or a set of two glass diffusers.

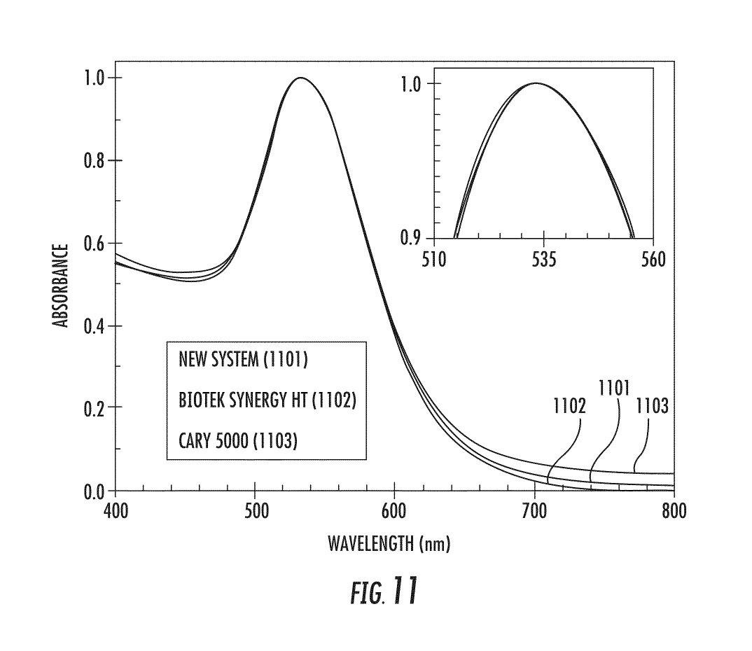

As a tungsten-halogen lamp can be approximated as a blackbody source, the red and near-infrared light will dominate shorter wavelengths. A tungsten-halogen lamp has a blackbody-like emission spectrum, so the blue portion of the spectrum is reduced in comparison to the red and near-infrared regions. First, a metallic neutral density (OD=1) filter was used to strongly attenuate near-infrared light. By adding a blue light balancing filters (Hoya Optics, LB120), the red light could be reduced, the peaking was reduced ad shifted from a maximum at 647 to 565 nm. FIG. 11 shows results obtained using our system in comparison with results obtained two commercial systems (Cary 5000 and Shimadzu UV-3600) for the same sample of gold nanospheres.

### Example 2

### Plasmonics for Enhanced Photovoltaic Absorption

Disclosed herein is the use of plasmonic particles for increasing the absorption in thin-film photovoltaic devices. Plasmonic light trapping is converted into low band-gap thin film solar cells to increase absorption of light in the red-NIR portion of the solar spectrum that is not efficiently absorbed in typical thin film cell. By focusing on plasmonic nanostructures that can be colloidally fabricated and deposited, the advantages of plasmonic light interactions are gained, without disrupting the crucial cost advantages of thin film solar cells in a practical manner. The method can be applied in standard environments and can be tuned for various semiconductor materials. Calculations have shown that relative efficiency gains exceeding 25% can be achieved if near-infrared light can be effectively captured in thin film solar cells.

### Nanoparticles Embedded in the Active Absorber Layer

Nanoparticles embedded in the active absorber layer were considered. In this case, plasmonic nanoparticles can improve the absorption efficiency in several ways. First, the particle absorption loss is mitigated by the strong absorption of short wavelength light in a very thin region at the top of the cell, which results in very little short wavelength light reaching the nanoparticle. This is an important effect, because the parasitic losses are much higher for these wavelengths. Furthermore, both back-scattering and forward scattering is beneficial for improving absorption within the semiconductor layer. Lastly, near-field enhancement may contribute to a localization of absorbed energy within the cell. It is noted that charge collection efficiency is generally low near the interfaces and high near the cell junction.

For all calculations, custom-written codes based on Mie theory based codes developed following the discussion presented in Bohren and Huffman were used (Huffman, C. F. Bohren and D. R. Absorption and Scattering of Light by Small Particles. Wiley-VCH, Weinheim, Germany, 2004). These codes are written with Matlab to calculate the electromagnetic fields (electric E, magnetic B, and Poynting vector S) at any point in space inside or outside the coated spherical particles in Cartesian or spherical coordinates. All fields are presented relative to the incident intensity of the non-enhanced fields of the incident light at that location in space.

The refractive indices for the dielectric materials water and amorphous silicon dioxide (silica) are calculated using Sellmeier-type fits to experimental observations. All other material refractive indices are interpolated from tabulated experimental data, including metals (Palik, E. D., ed. Handbook of Optical Constants of Solids. Academic Press, New York, U.S.A., 1985), cadmium telluride (Palik et al.), copper (indium, gallium) diselenide (CIGS) (P. D. Paulson, R. W. Birkmire, and W. N. Shafarman. Optical characterization of CuInl-xGaxSe2 alloy thin films by spectroscopic ellipsometry. Journal of Applied Physics, 94, dx.doi.org/10.1063/1.1581345 (2003), 879-888) and silicon (Green, M. A. Self-consistent optical parameters of intrinsic silicon at 300 K including temperature coefficients. Solar Energy Materials and Solar Cells, 92, dx.doi.org/10.1016/j.solmat.2008.06.009 (2008), 1305-1310). The optical properties of crystalline silicon are used here to represent the optical properties of micro-crystalline silicon, as relatively small differences are observed in the useful portion of the solar spectrum (400-1100 nm). A typical indium to gallium ratio of 0.3:0.7 was used for the CIGS material. The AM 1.5 solar spectrum is used for the distribution of solar intensity as a function of wavelength [NREL 2003].

### Nanoparticle Optical Properties in Solar Absorber Materials

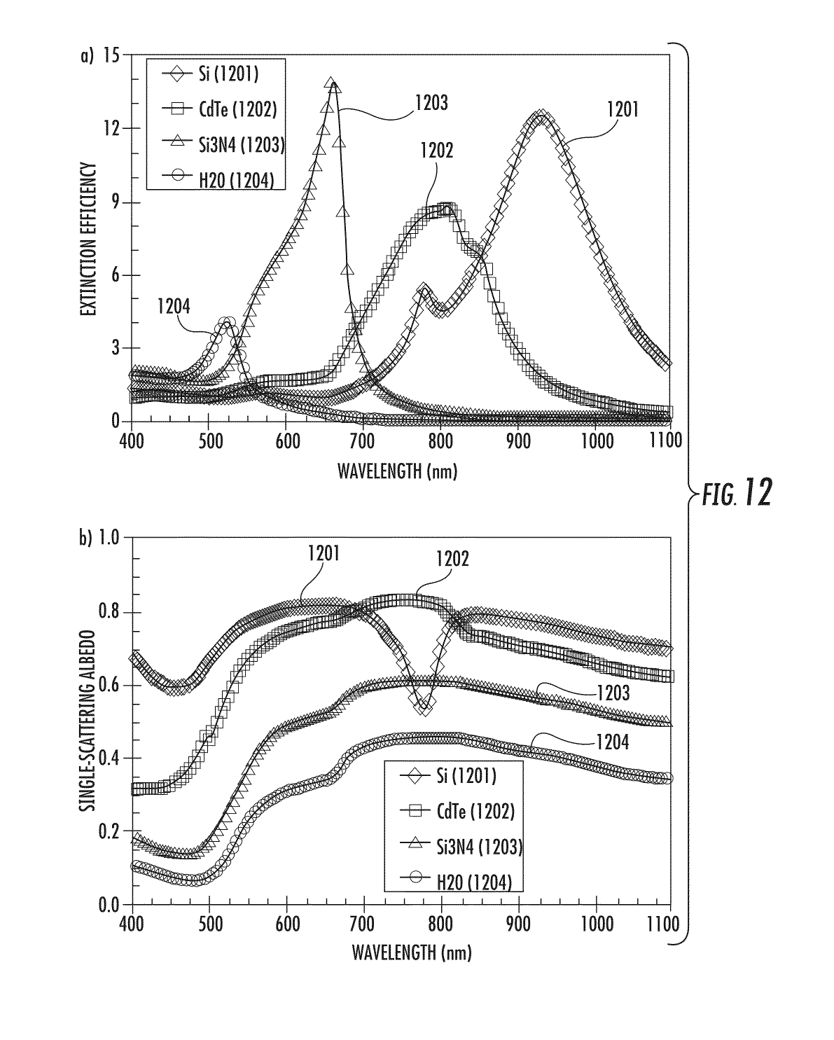

FIG. 12 shows the effects of an absorbing media on the resonance of plasmonic nanoparticles. There is a large red-shift in the plasmonic resonance when changing from water to solid materials, and a strengthening of the resonance. As shown before for a dyed water medium, a dramatic increase in the scattered fraction of the particle in the two absorbing solar materials (CdTe and μc-Si) was also observed, when compared with two non-absorbing dielectric media (H₂O and SiNₓ). This is a very important result for the use of plasmonics for solar cells, as absorption by the particle represents a parasitic loss and scattering is desirable for promoting absorption in long-wavelength regions where the absorption length is larger than the thickness for thin film materials. These results expand on previous results for plasmonic enhancement in absorbing materials and demonstrate the promise of plasmonics embedded in real solar absorber materials.

### Dielectric-Coated Plasmonic Nanoparticles

A complete treatment of the use of plasmonic nanoparticles embedded in the active absorber material for solar applications should also address potential charge-carrier losses at the metal sphere surface. Metal surfaces within a solar cell could act as trapping locations, resulting in decreases in the ability to separate charges and the corresponding efficiency of a photovoltaic cell. Typical plasmonic materials such as gold and copper act as especially effective recombination sites, enhancing the importance of this dielectric shell coating technique. Thin dielectric layers can have dramatic effects on electronic properties at an interface, so the presence of a thin dielectric shell around metal nanoparticles was considered in an effort to mitigate the effect of trapping.

Exposed metal surfaces within the active layer can drastically reduce charge collection efficiencies, so silica shells on metal nanoparticles are proposed to mitigate charge trapping at the metal surface. However, it is necessary to keep the silica shell as thin as possible to avoid damping the plasmonic response and avoid losing near-field enhancement that could otherwise be used to enhance solar absorption by the medium.

To estimate the shell thicknesses necessary to effectively insulate the silver surface from the surrounding medium and prevent charge carrier trapping, the measurements of leakage current in a metal-oxide-semiconductor field effect transistor (MOSFET) are examined as a function of silicon dioxide thickness. Hou et al. showed that an increase in the oxide layer thickness of approximately 1 nm was sufficient to reduce the leakage current at the gate by ˜5 orders of magnitude at a voltage of 1 V, which is estimated be similar to the conditions within the solar cell (Y. T. Hou, M. F. Li, Y. Jin, and W. H. Lai. Direct tunneling hole currents through ultrathin gate oxides in metal-oxide-semiconductor devices. Journal of Applied Physics, 91 (2002), 258-264). Similarly, Zhao et al. found that a native oxide layer, usually around 2.1 nm thick, on silicon increased the sheet resistance by more than two orders of magnitude in an electrode/oxide/semiconductor testing configuration of silicon nanomembranes (X. Zhao, S. A. Scott, M. Huang, W. Peng, A. M. Kiefer, F. S. Flack, D. E. Savage, and M. G. Lagally. Influence of surface properties on the electrical conductivity of silicon nanomembranes. Nanoscale Research Letters, 6 (2011), 402). These results suggest that an oxide thickness of ˜2 nm should be sufficient to effectively insulate a metal surface. Previously, we showed that thin silica shells can be fabricated on silver cores during synthesis.

### Coated Spheres in an Absorbing Medium

The Mie theory equations were extended for the electromagnetic fields at all points inside and around a coated sphere in an absorbing medium. The spherical harmonic coefficients can be solved for using direct matrix inversion of the coated sphere boundary conditions. The fields can then be obtained using the same equations as an uncoated sphere in an absorbing medium.

The calculation of spheres coated with concentric layers can also be solved analytically (Kerker, A. L. Aden and M. Scattering of Electromagnetic Waves from Two Concentric Spheres. Journal of Applied Physics, 22 (1951), 1242-1246). This solution has become relevant for plasmonics as nanoparticle synthesis methods for creating spherical shell coatings have recently been developed for metal core/dielectric shell, dielectric core/metal shell, bimetallic shell structures and multilayer concentric structures. Coated sphere calculations follow the same spherical harmonic solution method as Mie theory, but new scattering coefficients must be found using the boundary conditions at each of the interfaces. Once the updated electric and magnetic field coefficients are obtained, the fields inside the core and outside the shell can be solved using the same equations as for an uncoated sphere. Coated sphere (shell) calculations were verified by setting the core and shell to be the same material or by setting the core and environment to be the same material and comparing the results with extended Mie theory calculations. Coated sphere calculations were tested two ways: first, a direct derivation following previously published work (Huffman 2004), and second, direct solution of the system of linear equations set up using the boundary conditions through matrix inversion.

### Effect of a Silica Shell on the Plasmonic Resonance

The optical effect of a shell between a metal and a semiconductor can be quite dramatic. Large blue-shifts in the plasmon resonance wavelength are observed for Ag®SiO₂ nanoparticles in silicon, although they are not observed for Ag®SiO₂ particles in water. This blue-shift is especially important for plasmonic solar applications, Silica coatings also allow for larger particles (and correspondingly higher scattering-to-absorption ratios) than would be normally feasible for a given material band-gap, because the red-shift that comes with increasing particle size can be counteracted by the blue-shift that occurs due to the silica shell.

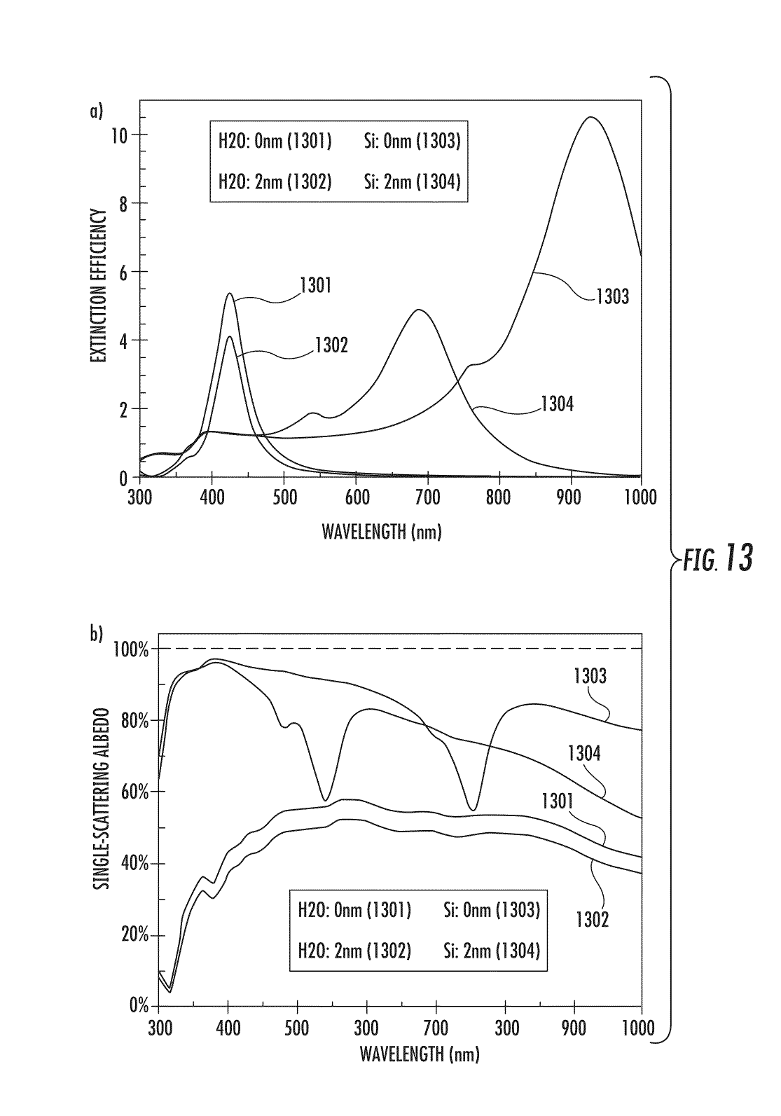

FIG. 13 shows the effect of a thin silica shell and an absorbing medium on the plasmonic response of a silver nanoparticle. The scattering efficiency (solid lines) and the scattering-to-extinction ratio (dotted lines, right axis) are shown. The configurations include a 50 nm Ag nanoparticles in: water, water with a 2 nm SiO₂ shell, microcrystalline silicon (pc-Si) medium, and μc-Si medium with 2 nm SiO₂ shell.

These results reveal, first, that the silica shell results in only a slight red-shift in a water medium. For a μc-Si medium, however, a thin silica shell results in a dramatic blue-shift in the resonance. This behavior occurs because of the relative difference between the optical properties of the silver sphere and the shell relative to the surrounding medium. Interestingly, the presence of an absorbing medium still results in a significantly enhanced scattering-to-extinction ratio.

### Plasmonic Enhancement Mechanisms

For plasmonic nanoparticles embedded in an absorbing medium, both enhanced near-field absorption and increased path length due to scattering by the particle lead to increased absorption by the semiconductor. An understanding of the dominant mechanism of enhanced energy deposition is extremely important for the effective design of plasmonic particles for solar applications. Both contributions to the enhanced optical absorption in thin film photovoltaics were evaluated.

The near-field absorption can be calculated by examining the extra light absorbed in the near-field around a plasmonic nanoparticle using a point-by-point method using the divergence of the Poynting vector at each location. The loss from absorption by the particle and the displacement by the particle are considered for determining the net effect of the particle.

To determine the total amount of extra energy deposited in a medium due to a plasmonic particle, one must also examine the scattered light in addition to enhanced near-field energy deposition. Scattering in the perpendicular directions will provide a net gain in absorption within the cell for photons with energies greater than the band-gap, as the lateral dimensions of thin film solar cells are typically much larger than the thickness. This effect can also be considered in terms of the coupling of incident light into guided modes, where the absorption path length can be much larger than the thickness of the cell.

The angular distribution of energy scattered outside the near-field region was examined to determine the increase in absorption within the medium on account of plasmonic scattering. Plasmonic particles are of significant interest for increased scattering in solar cells because of their strong high-angle scattering relative to dielectric particles, which scatter light primarily in the forward direction. The light that scatters from the particle (outside of the near-field region) is ray-traced to the interface, reflection is calculated, and then the reflected ray is traced to the opposite surface. The total amount absorbed on each path is calculated from the reflection losses at each surface. We follow each ray until it reaches 0.1% of its initial intensity. The enhanced path length and corresponding absorption is calculated with ray tracing and using complex Fresnel equations to determine reflection at the cell boundaries. This rigorous approach builds on an initial estimate that can be obtained by determining the percentage of light scattered in the lateral (x and y) directions. By calculating the scattered light outside of the near-field region, ‘double counting’ any absorption is avoided, while still being able to account for all sources of absorption. The total gain in absorption by the semiconductor layer from scattering is calculated for each wavelength by integrating the angular contributions for each polar angle.

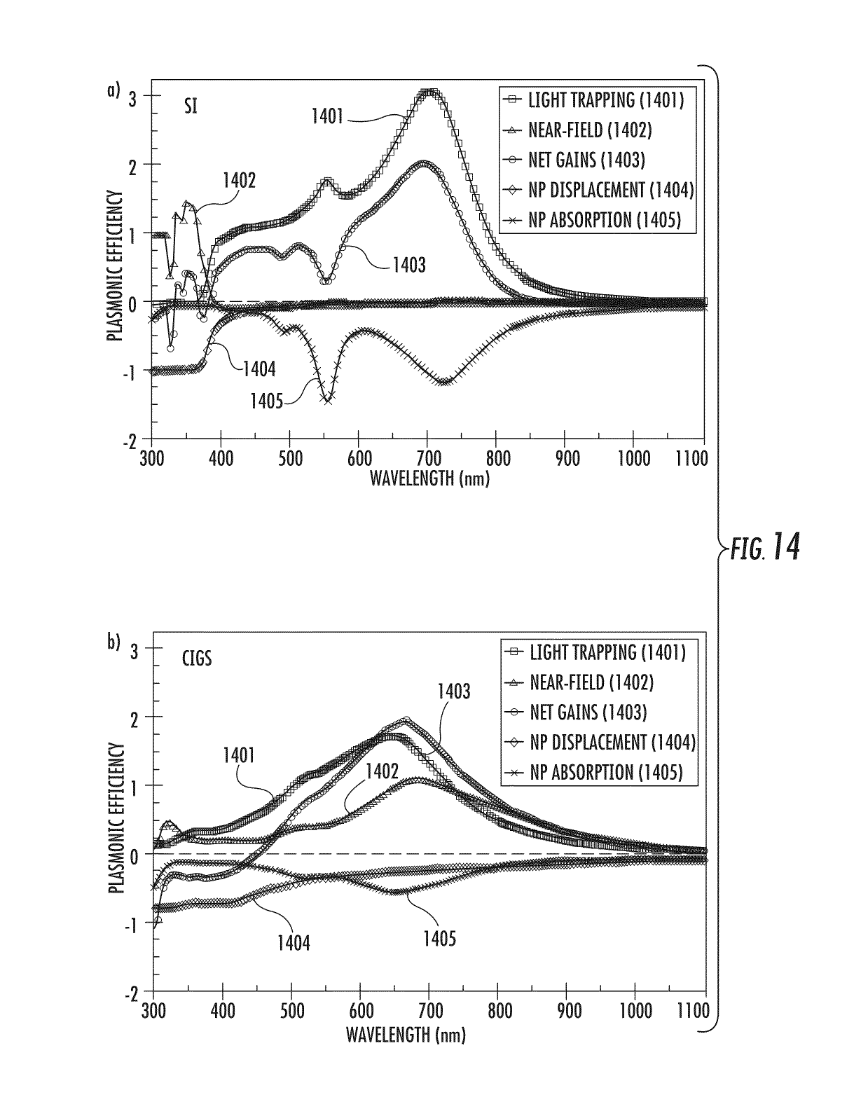

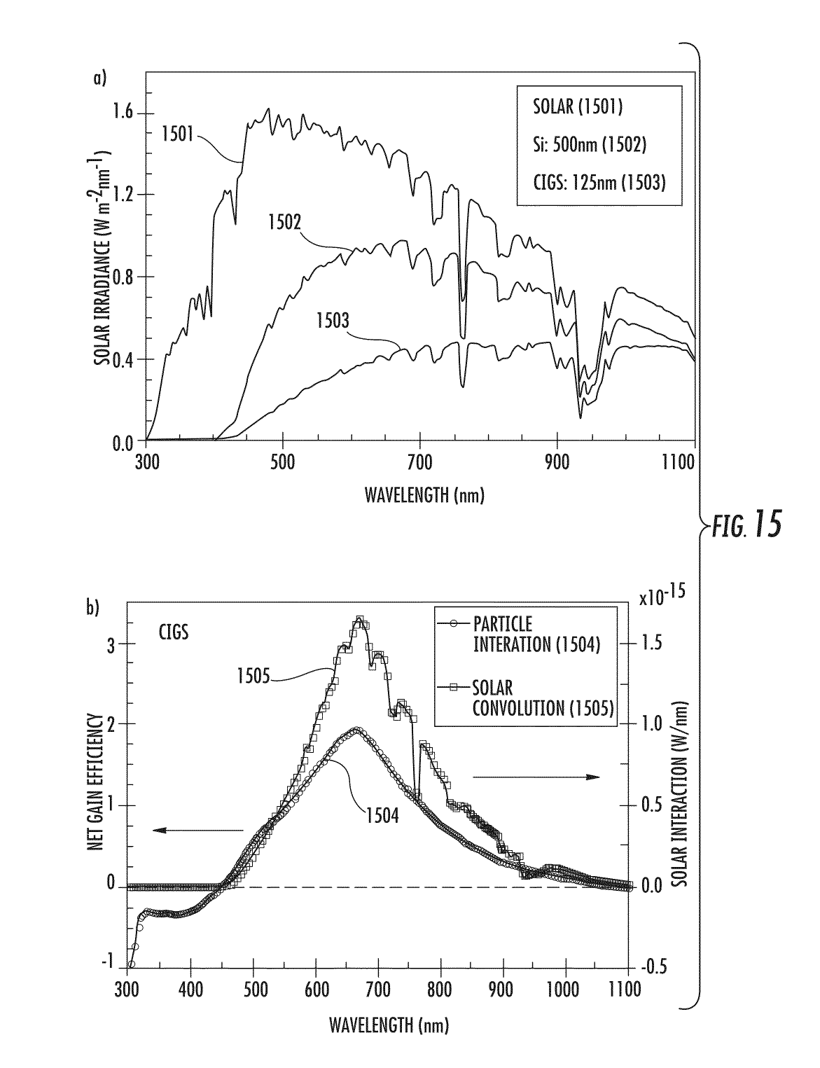

FIG. 14 shows each of the mechanisms that contribute to enhanced plasmonic absorption in photovoltaic semiconductor materials. Two materials are shown: μc-Si, which is an indirect (weak) absorber (FIG. 14(a)), and CIGS, which is a direct (strong) absorber. In this figure, the path length enhancement through scattering from the particle is denoted ‘light trapping’, while the plasmon-enhanced absorption around the nanoparticle is shown as the ‘near-field’. The two loss mechanisms are displacement of absorber material by the particle and absorption by the nanoparticle. The sum of all these values is shown as the net gain, which is positive for most of the solar spectrum but is negative for short wavelengths.

Several points can be drawn from these results. First, the peak plasmonic gains are similar for both of these materials, but the contributing terms are different. Near-field and scattering effects for energy absorption, which was previously unavailable, are distinguished Enhanced light trapping through scattering is completely dominant for weak absorbers, such as μc-Si, but the near-field absorption is important for strong absorbers, becoming the major source of enhancement for CIGS at long wavelengths. The loss due to displaced absorber is found to be a correspondingly weak effect for μc-Si, but is significant for CIGS. These results show that a back surface location for plasmonic elements may be more advantageous for strong absorbers.

### Effect of Depth in Plasmon-Enhanced Thin Film Absorption

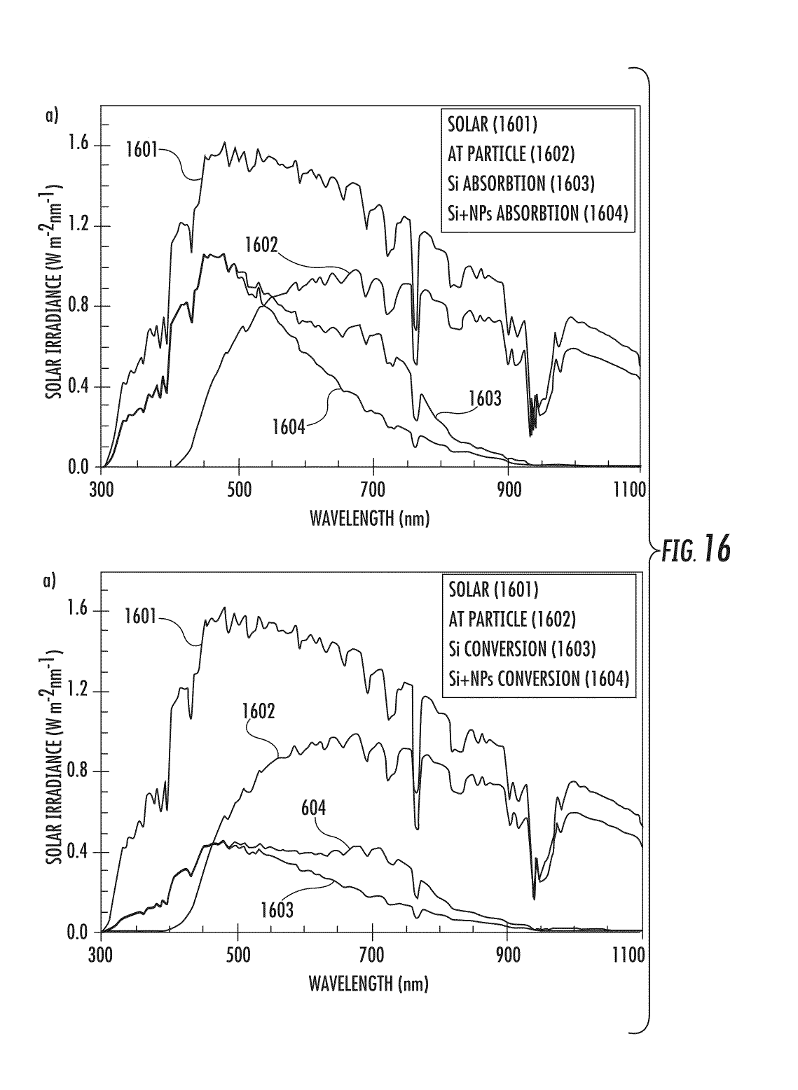

Plasmonics for solar cell applications can most effectively be used by placing plasmonic particles some distance into the material, thus mitigating the effect of wavelength regions where the particle has a negative effect. This works because the absorption lengths for short wavelengths are very small, meaning that this light will all be absorbed by the depth of the particle. While the incident spectrum at the surface well-known, the depth of the particle in the solar cell has a large effect on the spectrum present at the particle. Here particles embedded at the midpoint of the solar absorber medium are examined. The wavelength-dependent light intensity at the particle location is first determined (FIG. 16(a)), which is significantly modified from the incident solar spectrum. Specifically, the short wavelength light is absorbed while long wavelength light mostly passes. This wavelength-dependent attenuation must be considered for each depth and system chosen, and it is an important effect for the use of embedded nanoparticles, as significantly reduced fractions of light reach the particle in the short wavelength portion of the spectrum where the plasmonic gain is low. FIG. 16(b) shows the convolution of the intensity distribution of the solar spectrum with the previously calculated net wavelength-dependent gain from the presence of particle. In this case, it is seen that though there are regions where the nanoparticle would have a negative effect, placing the particles well within the absorber medium results in a net gain at all wavelengths. This configuration (b) in FIG. 16, significantly optically outperforms (a) for 2 major reasons. 1) Reduced parasitic losses from particle absorption at short wavelengths. 2) Better coupling of light scattered from the plasmonic particle into the absorbing medium, as much of the light scattered by a particle on the surface is reflected out and not participate in guided modes. Furthermore, the configuration b) can outperform configuration c) because of increased coupling into guided modes, reduce losses at back surface, and the benefit of enhanced near-field absorption.

### Embedded Ag@SiO2 Nanoparticles for Enhanced Solar Absorption in Thin Film Photovoltaics

Silver nanoparticles coated with a thin silica shell (Ag®SiO₂) were considered for photovoltaic applications. Silver nanoparticles were used for this application because of the cost, strong, blue-shifted plasmonic response and improved scattering to absorption ratio relative to gold spheres. Here we consider silver core nanoparticles coated with a thin silica shell (Ag®SiO₂) for enhanced photovoltaic applications. Thus, a 2 nm SiO₂ coating on a 25 nm silver core is considered to yield a 54 nm overall particle size. Spheres are used because they have the shortest resonance of all shapes. This is important because of the strong red-shift that occurs when embedding particles in semiconductor media. A spherical particle shapes could be used in the case of aluminum nanoparticles (which have a very blue shifted resonance).

A silica glass superstrate configuration, with an aluminum back surface, was used. The effects of reflection from the air-to-glass and glass-to-silicon interfaces are examined In the simulations, the particles are spaced in a hexagonal close-packed pattern such that the extinction and near-field areas at the plasmon peak will not overlap. Thinner cells yield higher performance gains, but the goal of producing higher overall efficiency cells requires a balance between absorption and plasmonic enhancement. A minimum absorber thickness of 10 times the nanoparticle core radius is made to minimize the effect of interfaces and to ensure that ‘bulk’ environment conditions apply.

The contribution of plasmonic nanospheres embedded in absorbing media is analytically determined to total optical absorption. The overall gain as a function of wavelength in terms of the absorption and conversion to useful electrical energy is measured. FIG. 16 shows the solar spectrum, calculated optical power absorbed and optical power converted for both plasmon-enhanced and unenhanced μc-Si solar cell. The displacement between the red and blue lines represents the differences induced by the plasmonic nanospheres incorporated into the cell. A pronounced increase in the absorption was observed near the peak of the nanoparticle plasmonic response for the net gain.

A similar analysis for CdTe and CIGS absorber layers was completed. The μc-Si cell in the previous example is 1000 nm thick, but a 250 nm thick CIGS and CdTe absorber layers were considered because of their strong absorption. The effect of increasing the nanoparticle size for the thicker μc-Si cell was compared. These data are presented in Table 3.

TABLE 3
Comparison of the predicted enhancements for Ag@SiO2
nanoparticles embedded in various thin film solar absorber
materials. The SiO2 shell thickness is 2 nm for all cases.

| | μc-Si | μc-Si | CdTe | CIGS |
|---|---|---|---|---|
| Absorber Thickness (nm) | 1000 | 1000 | 250 | 250 |
| Ag Core Diameter (nm) | 100 | 50 | 50 | 50 |
| Estimated Absorption Without | 210 | 210 | 393 | 553 |
| NP's (W/m²) | | | | |
| Gain from Perpendicular Scattering | 126 | 77 | 49 | 32 |
| (W/m²) | | | | |
| Gain From N.F. Absorption | 3 | 2 | 22 | 28 |
| (W/m²) | | | | |
| Loss due to Displaced Absorber | −2 | −1 | −5 | −9 |
| (W/m²) | | | | |
| Loss due to Particle Extinction | −30 | −22 | −42 | −42 |
| (W/m²) | | | | |
| Net Gain in Absorption (W/m²) | 94 | 56 | 52 | 10 |
| Estimated Total Absorption | 306 | 266 | 445 | 563 |
| (W/m²) | | | | |
| Estimated Total Conversion | 118 | 97 | 137 | 154 |
| (W/m²) | | | | |
| Estimated Absorption Gain with | 46% | 27% | 6.0% | 1.7% |
| NP's | | | | |
| Estimated Conversion Gain with | 65% | 36% | 7.7% | 2.5% |
| NP's | | | | |

The simulated results clearly show that nanoparticles can be used to increase absorption, locally and through scattering, for thin film solar materials. It appears that silica coating on metal nanoparticles can mitigate the effects of charge carrier trapping, provided that crystalline quality can be maintained in the surrounding medium. In a practical embodiment, the material displaced forms bumps on the surface, providing additional light trapping effects.

### Evaluation of Nanoparticles Embedded in the Active Absorber Layer

### Thin Film Deposition and Characterization

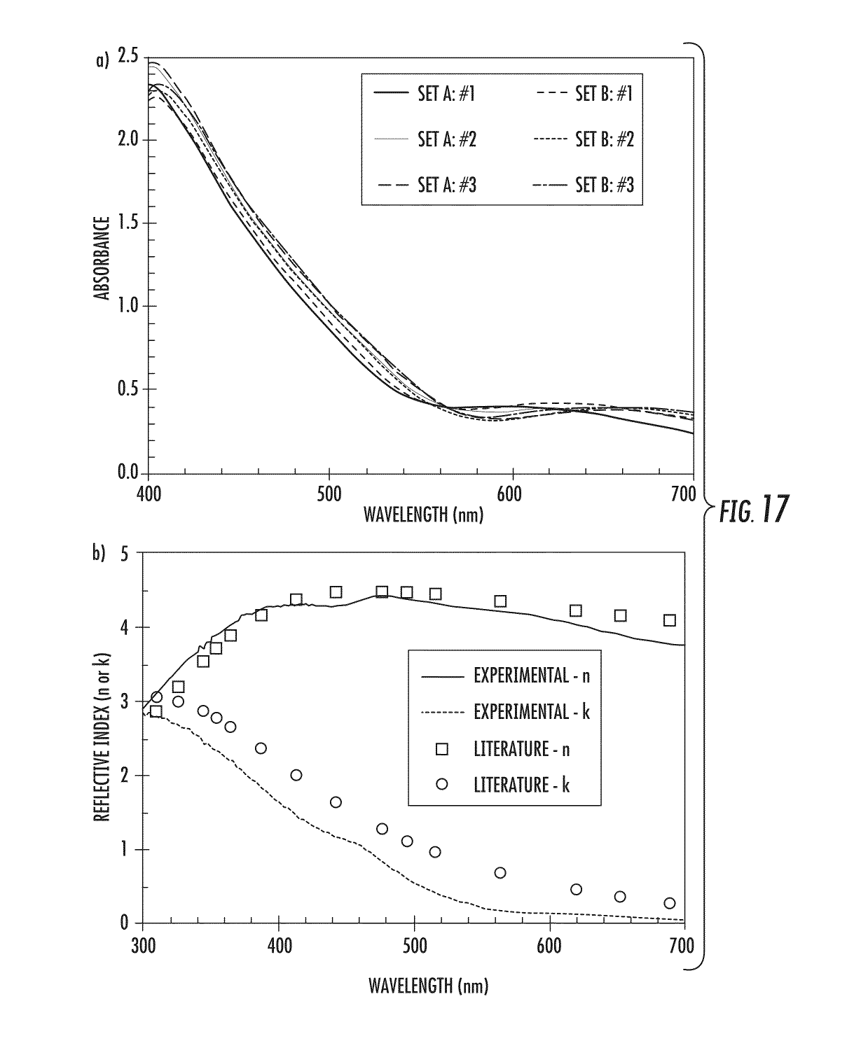

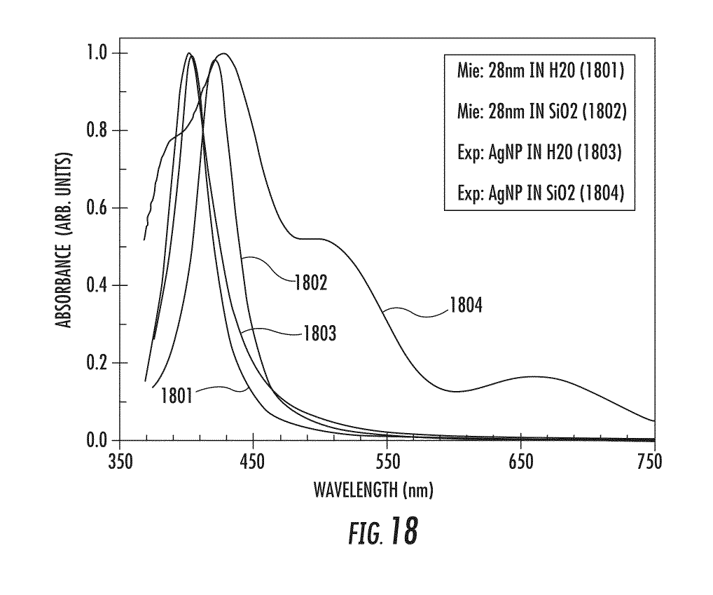

Plasma-enhanced chemical vapor deposition was used (PE-CVD, Oxford Plasmalab 80+) for the deposition of amorphous silicon, silicon dioxide, silicon nitride, and for mixed amorphous-microcrystalline silicon. In PE-CVD, constituent gases are flowed into the deposition chamber at a near-vacuum, and then ignited into a plasma through the deposition of radio-frequency excitation (13.56 MHz). In a typical deposition, 250 nm of silicon was deposited onto a 3×3 array of pre-cleaned polished glass or indium tin oxide (ITO) coated slides, where the thickness was confirmed by surface profilometry. FIG. 17 shows the consistency and optical properties of the deposited thin films through optical absorbance and ellipsometry measurements.

These results show that the deposition is consistent across the deposition window and that the deposited films are primarily amorphous in nature, although some microcrystallinity or void content can be deduced from the somewhat reduced imaginary refractive index component.

Nearly pure microcrystalline silicon can be deposited using PE-CVD if hydrogen or helium feed gases are available. Alternatively, high pressures, radio frequencies, temperatures or plasma powers can also be used to promote the formation of microcrystalline silicon. Additionally, small amounts of impurity gases such as phosphine (PH₃) or diborane (B₂H₆) can be used to directly create doped layers for the fabrication of complete solar cells.

### Nanoparticles Embedded in Plasma-Deposited Materials

Sub-monolayers were created by immersing freshly-cleaned substrates into a 1% (v/v) ethanolic solution of aminopropyltriethoxysilane (APTES), wash with copious ethanol, dry briefly at 80° C., then place into a nanoparticle solution. This procedure leads to extremely homogenously layers across expanses of 1″×1″ using gold and silver nanoparticles.

The ability of plasmonic nanoparticle monolayers to integrate into thin-film photovoltaic materials with standard fabrication techniques was tested. This was done by sandwiching plasmonic nanoparticle monolayers between thin film dielectric layers fabricated with PE-CVD, which is often used industrially for the deposition of thin silicon films. The absorbance of the plasmonic nanoparticles on the substrate before and after the top layer deposition was observed to check that the nanoparticles remain on the surface, i.e. that they are not removed during the plasma deposition step, and to test the expected plasmonic shift for a nanoparticle embedded in a solid material.

The results show that the plasmonic peak red-shifts when the surrounding medium is silica rather than water. The discrepancies observed between simulation and experimental results for nanoparticles embedded in the glass can be explained because of the assumption of the glass slide and plasma-deposited thin film consisted of glassy silica, where in both cases the optical properties differ slightly. The broad peaks at 520 and 670 nm are probably the result of agglomeration on the surface. The observation of a strong plasmonic peak resulting from nanoparticles monolayers embedded in the glass layer is a proof-of-concept showing the feasibility of the approach.

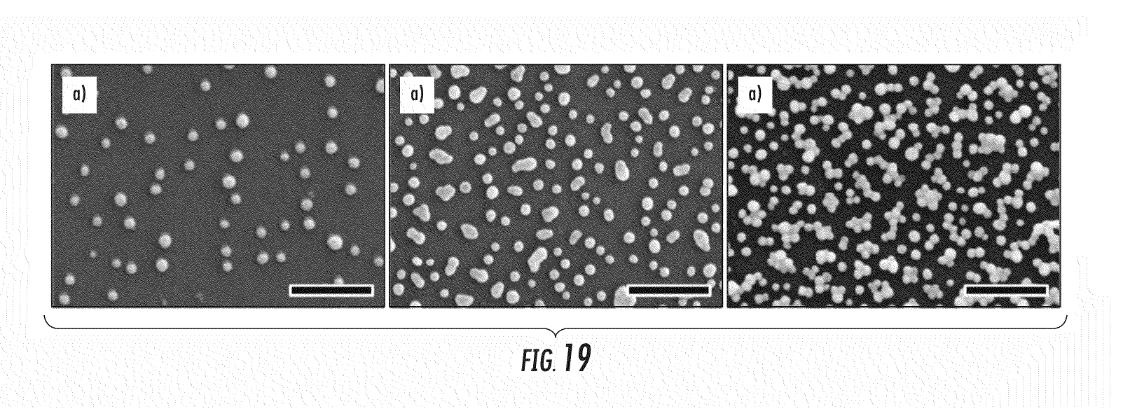

For effective use in solar applications, the surface density and spacing of the particles embedded in the absorber material must be controlled. Adjusting the concentration of the nanoparticle solution was found to provide the desired level of control. FIG. 19 shows the spacing of gold nanoparticles on a glass substrate for three different colloidal concentrations.

It is observed that the spacing increases as the concentration decreases (FIG. 19). It is also seen that the higher concentrations lead to agglomeration of the nanoparticle, which will broaden and red-shift the well-defined plasmonic response of isolated metal nanoparticles. A typical dilution ratio of 33% for all further photovoltaic monolayer work was used to avoid agglomeration and achieve sufficient coverage. Evenly distributed sub-monolayers of Ag®SiO₂ nanoparticles on both glass and silicon substrates were also achieved. It was necessary to centrifuge and resuspend Ag®SiO₂ in water before the self-assembly step, as no nanoparticles would attach to the surface while the nanoparticles were suspended in the ethanol-water mixture that the shells are grown in, which we attribute to surface charge effects. Formation of Ag®SiO₂ sub-monolayers on a substrate enabled the testing of the conditions identified in the simulation section for the enhancement of absorption in thin silicon films.

### Effect of Dielectric Shell on a Plasmonic Particle in an Absorbing Medium

The simulations shows the dramatic effect of a thin dielectric shell on a metal nanoparticle embedded in an absorbing medium. This optical behavior was tested by first fabricating a set of different thickness silica shells on a single set of silver nanoparticle cores by varying the concentration of TEOS for a defined nanoparticle concentration. The peak shift of these different shells can be used to determine their thickness. The silver nanoparticles used in this study have a diameter of 60±7 nm. These core-shell nanoparticles are organized into sub-monolayers embedded within 800 nm thin film of silicon on polished glass substrates. For this test, to more closely approximate simulations, increased plasma power and pressure in the PE-CVD fabrication stage was used to obtain thin films with a higher degree of microcrystallinity. These substrates, along with control samples that were fabricated without any integrated nanoparticles, were then tested with UV-Vis-NIR spectrometry to determine the wavelength-dependent absorbance of the Ag®SiO₂-Si composites.

At least six samples were measured for each silica shell thickness, plus seven control samples in total. Sharply increasing absorption of light below a wavelength of ˜600 nm was also observed. Thus, the integrated absorbance over the range of 600-1000 nm is considered as a measure of the effectiveness of plasmonic enhancement. The optical properties of Ag®SiO₂ nanoparticles with various shell thicknesses can improve absorption when embedded in silicon thin films. The initial nanoparticle core had a diameter of 36 nm and a plasmonic peak width of 64 nm (FWHM). The results of these studies are presented in FIG. 20.

### Plasmon Enhanced Thin Film Photodetector

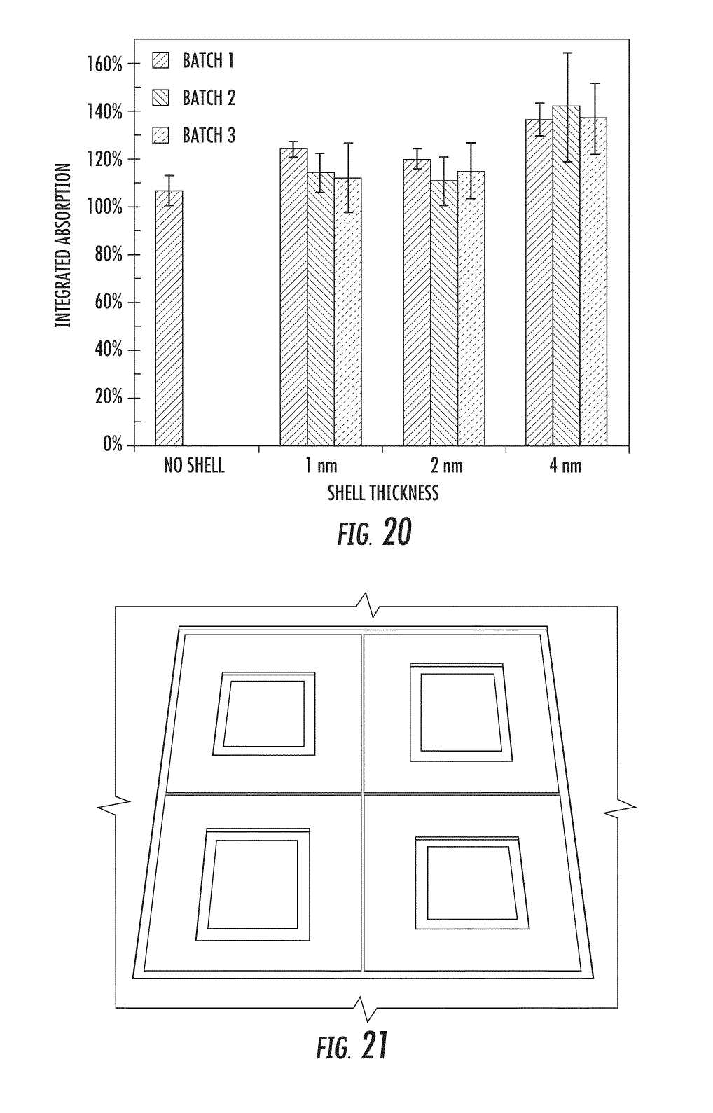

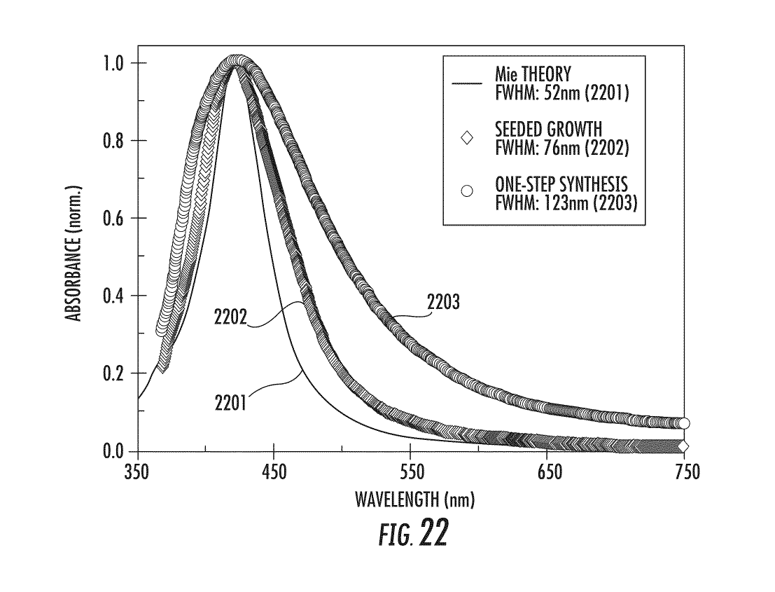

Thin film silicon photoconductive optical detectors were also fabricated as a final verification of the use of embedded plasmonic nanoparticles for the enhancement of red-NIR absorption within the semiconductor. Simulations were used to predict the magnitude of absorption by the particle and it was shown that scattering is be a much stronger effect in semiconductor materials, so it appears that enhanced absorption occurs in the silicon. Ag®SiO₂ nanoparticles were embedded in a silicon matrix surrounded by two electrodes as well. To fabricate these devices, indium tin oxide (ITO) coated polished glass superstrates were used. These provide both an electrode and an optically transparent window for coupling in incident light. The edges were then masked to avoid delamination of the silicon layer and also to provide surface area for the front contact. Subsequently, a thin silicon top layer (400 nm) was deposited using PE-CVD. This is used as the substrate for self-assembly of a sub-monolayer of Ag®SiO₂ particles following the previously described procedures. Then, another layer of silicon is deposited, sandwiching the nanoparticles in the silicon. Finally, a thin film silver back electrode is fabricated with thermal deposition. A set of four completed devices are shown in FIG. 21. Clear differences in the optical response are immediately apparent for the substrates with embedded plasmonic particles. In this case, the substrates are viewed from the backside, and the bright white reflection indicates higher surface roughness for the silver contact on account of the successfully integrated plasmonic nanoshell structures (bottom left and top right).

Before the back electrode was deposited, UV-Vis-NIR was performed on each of the cells. Two sets of samples were prepared, with control and test samples in each set. In the first case, the control is kept pristine, while in the second set, it is coated with an APTES monolayer, but no nanoparticles, to test absorption. It was found that the two control samples had similar integrated absorbances, even including the thin APTES layer. The two plasmon-enhanced cells, however, each had significant improvement in the absorption in the 600-1200 long wavelength region (38% and 45%).

These devices were tested by applying a voltage across the electrodes to provide a mechanism for separating photogenerated electron-hole pairs. Alternatively, the resistance was measured as a function of incident optical power for a white light source. Initial results indicate an improved photoconductive response that shows the presence of a plasmonic effect in this case, and not simply the surface roughness, resulting in increased absorption by the semiconductor. Thus, these experiments demonstrate plasmonic enhancement using a Ag®SiO₂ nanoparticle system driven by the use of simulations to predict successful configurations. This approach has identified an attractive use in full solar cell configurations.

### Example 3

### Procedures for the Synthesis and Delivery of Plasmonic Core-Shell Structures for Solar Applications

Disclosed herein is the process necessary to produce plasmonic nanoparticle structures that can be used to enhance the performance of thin film solar applications. First, a one-pot seeded growth process was developed with dual reducing agents to produce ultra-narrow size distribution silver nanoparticles across a size range from 4 nm seeds to 100 nm. Secondly, a method for using concentration to optimize and control the growth of silica shells on silver cores was carried out, which is crucial for obtaining plasmonic benefits without causing added recombination losses. Finally, conditions for effective 2D self-assembly of metal nanoparticles on dielectric and semiconductor surfaces were found through extensive experimentation. In this last step, new methods for depositing and controlling the density of nanoparticles on a surface were developed, and it was found that nanoparticle concentration and size were interrelated factors that needed to be considered for obtaining the desired nanoparticle coverage and attachment to the substrate. All these separate elements, used for the first time for solar applications, yielded an example for how dielectric-coated metal nanoparticles can be synthesized and deposited on photovoltaic materials as a positive implementation of the concept.

### Synthesis Methods for Size Control of Nanospheres

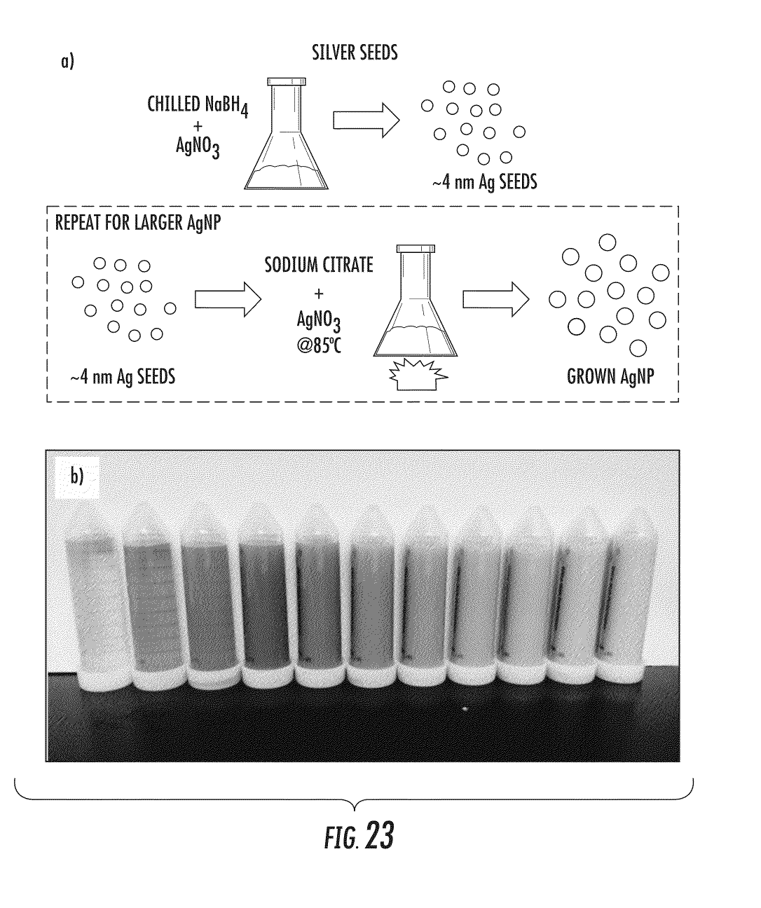

The UV-Vis-NIR spectra are shown in FIG. 22 for a narrow size distribution nanoparticle colloidal solution synthesized with the DR-SKSG method in comparison with the much wider size distribution particles synthesized with the Turkevich method. The electromagnetic simulation shown for comparison is for a single nanoparticle size, revealing the near-monodispersity of samples prepared using this new DR-SKSG method.

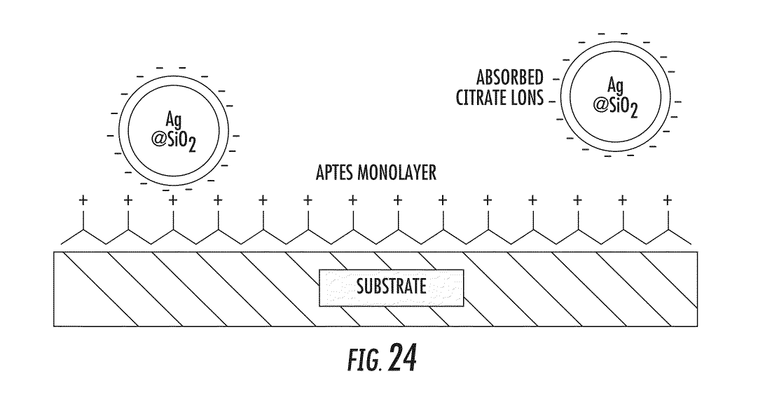

An interesting feature of the nanoparticle growth process was the significant narrowing in the plasmon peak during the first growth stage. This reduction in the peak width corresponds to a ripening process where smaller nanoparticles dissolve and the added silver in solution evens out the nanoparticle sizes. This novel dual reducing agent, SKG technique, where a size-focusing approach is applied to narrow nanoparticle seeds generated using a strong reducing agent, provides an effective and consistent method for producing high-quality silver nanoparticles of controlled sizes with narrow size distributions. A diagram of the modified SKSG process and an image of the nanoparticle solutions grown with this one-pot technique are shown in FIG. 23.

### Growth of Controlled Thickness Silica Shells

A method for electrically insulating the particles is essential for effective use of plasmonic nanoparticles for solar applications. To accomplish this goal, silica shells are formed onto metal nanoparticles.

### Optical Properties of Silica-Shell Coated Silver Nanospheres

The effect of various sizes of a silica (SiO₂) coating was modeled on a 50 nm diameter silver core. It is necessary to keep the silica shell as thin as possible to avoid damping the plasmonic response, while still providing the surface insulation necessary. Experimental evidence indicates that an oxide thickness of ˜2 nm is sufficient to effectively insulate a semiconductor-metal junction. Silver spheres were therefore simulated with SiO₂ coating with sizes varying from 1 nm to 10 nm.

The simulation results in FIG. 6 reveal a dramatic effect of a thin dielectric shell on a metal nanoparticle embedded in an absorbing medium (silicon, Si, commonly used for photovoltaic applications) on their plasmon resonance conditions. While bare silver particles embedded in silicon strongly red-shifts the plasmonic frequency, silica shells are found to blue-shift the plasmonic peak back to lower wavelengths towards the region of interest. This intriguing and previously undiscovered effect is of great importance for plasmonics in photovoltaic materials, and has a profound impact in their use for improving their efficiency.

The plasmonic resonance of a metal nanoparticle strongly depends on the local environment that affects the boundary conditions for electromagnetic interactions. For a metal nanoparticle in water (n˜1.33), the presence of a higher dielectric coefficient silica shell (n˜1.5) results in a weak red-shift in the plasmonic response in FIG. 6). However, when a metal nanoparticle with a silica shell is embedded in a microcrystalline silicon medium (n˜4), it has a very strong blue-shift effect on the plasmon resonance (FIG. 6).

This blue-shift property of silica coating on metal particles has an important advantage in tuning the particle size for achieving an optimized scattering to absorption ratio. To blue-shift the plasmon properties of bare silver particles in silicon, we need to reduce their size that results in the increase of their absorption and thus their parasitic losses. The silica coating enables us to tune the particle properties to the region of interest in the 600-900 nm range without needing to decrease the particle size, thus achieving the desired scattering properties and increase the internal light trapping and overall absorption of photons in this range.

### Synthesis Method of Silica-Shell Coated Silver Nanoparticles

Several different methods were first evaluated for silica shell growth. Procedures for coating metal nanoparticles with a silica shell generally consist of two primary processes. First, there must be a replacement of the existing surfactant or stabilization ions or molecules with a silicon-based molecule. For citrate-stabilized nanoparticles, this can be accomplished using aminopropyltriethoxysilane (APTES) or tetraetylorthosilicate (TEOS). When using APTES, only a monolayer can be grown effectively without causing aggregation, so extended intermediate growth must be taken with activated silica. The next step involves the growth of the silica shell in a Stöber process, typically in an ethanol-based solution using TEOS. The initial experiments with both techniques found that the TEOS-based initial coating with subsequent growth to provide the most consistent and useful results with a rapid and simple process, so all further silica shell growth procedures were completed in this manner.

It is necessary to control the thickness of the shell to tune the plasmonic resonance to the optimum condition within an absorbing material, while also mitigating the electron trapping problem for exposed metal surfaces in photovoltaic cells. Prior results in the literature indicate that 2 nm thickness of SiO2 is sufficient to greatly reduce conductivity or electron interaction with metal surfaces. Silica coatings as thin as 2 nm have previously beenfabricated on gold nanoparticles by using a dual silica source growth process, with APTES and active silica created using an active exchange resin with hydrochloric acid, mixed in a basic solution over the course of 24 hours (L. M. Liz-Marzan, M. Giersig, and P. Mulvaney, “Synthesis of Nanosized Gold-Silica Core-Shell Particles,” Langmuir, 12 (1996).

The method was modified to achieve a simpler method that could be employed to repeatably synthesize thin shells on silver cores. The thickness of the silica coating as well as enhancement of the stability of the silver particles during silica growth was achieved by changing the concentration of nanoparticles with respect to the chemicals. To achieve a thinner silica coating, the initial concentration of nanoparticles in ethanol was increased from 20% as suggested in the previously published procedures to 40%. It was found that this increase in particle concentration or reduced in ethanol concentration also improved the stability of silver particles. Small silver nanoparticles with thin shell structures were unstable in the 80% ethanol solution used for gold nanoparticles but very stable when it was decreased to 60%. The rapid formation of a thick silica shell stabilizes the nanoparticles, but higher aqueous nanoparticle colloid concentrations lead to improved stability. A range of thicknesses was synthesized on silver spheres to demonstrate control of the thickness.

### Deposition of Uniform Monolayers of Core Shell Structures on Photovoltaic Materials

In thin-film organic photovoltaics, the nanoparticle colloid can be directly mixed in with the polymer solution. For dye-synthesized cells, dielectric-coated metal nanoparticles can be sintered together, as is commonly done with titania microparticles. To fully utilize nanoparticles in thin film semiconductor photovoltaic configurations, it is crucial to assemble nanoparticles in a monolayer on the surface with uniform spacing between the particles. Simple solution dipping results in extremely variable surface concentrations and ‘coffee ring’ type nanoparticle deposition patterns, which are useless for plasmonic photovoltaic enhancement. This method can allow for the sandwiching of nanoparticles at a desired location within a semiconductor material by completing this process in between semiconductor deposition steps. It was found that once attached to the surface, the nanoparticles are not removed or damaged by subsequent depositions.

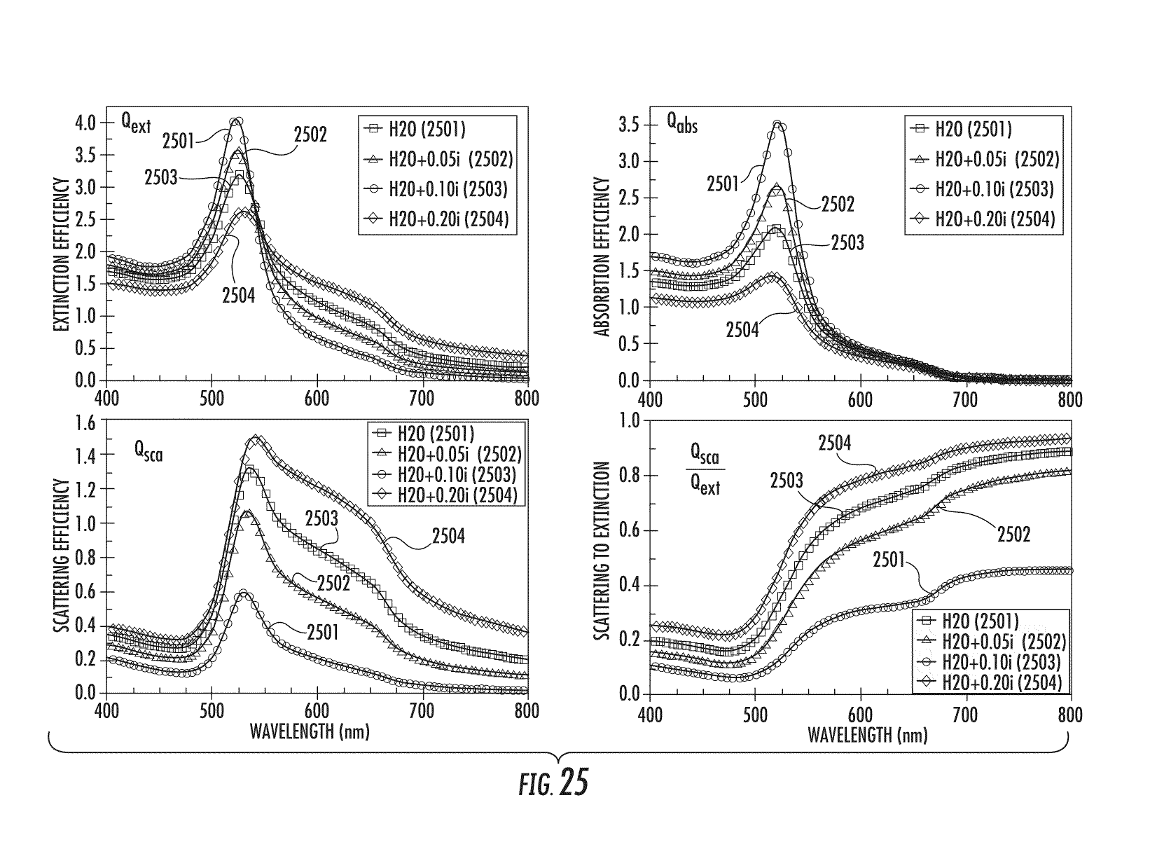

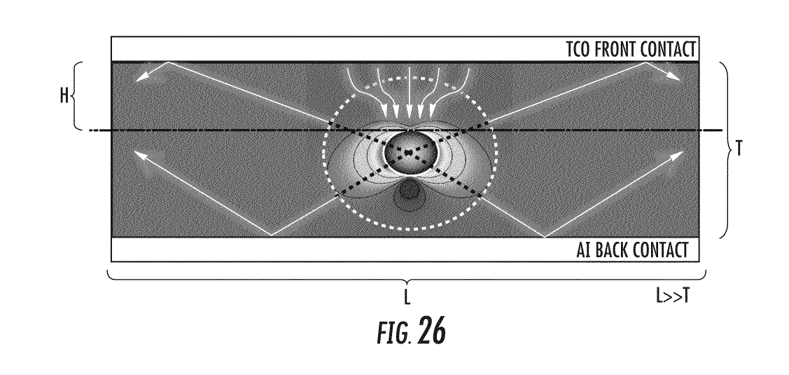

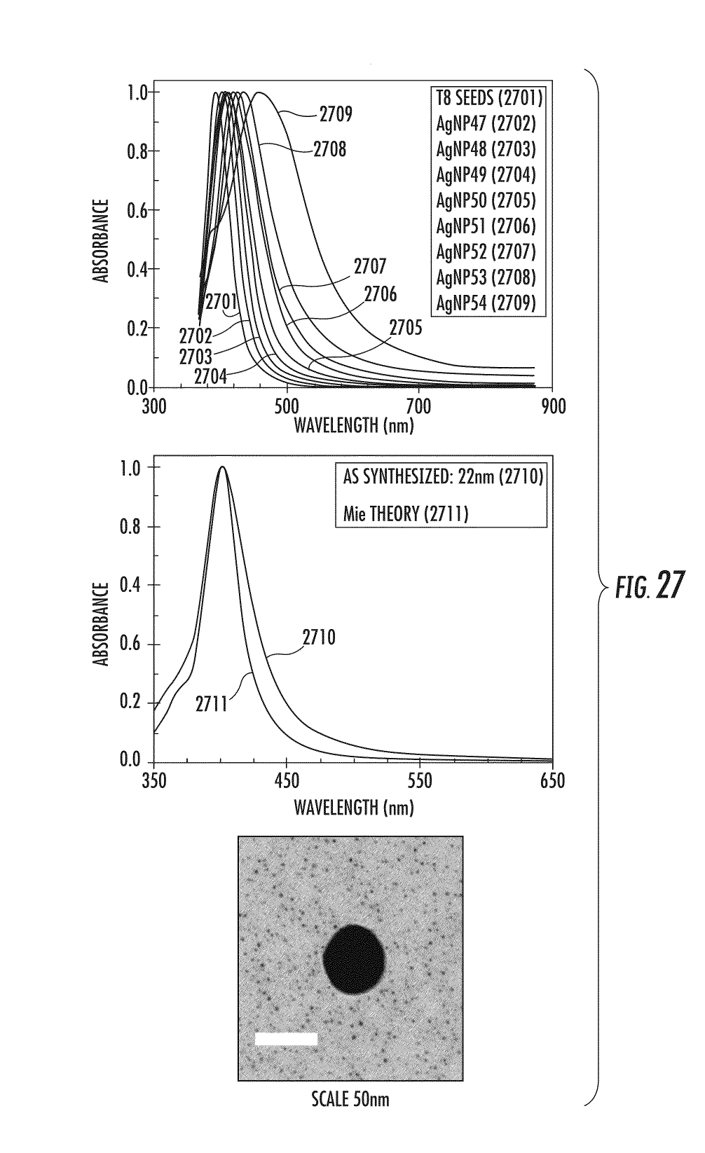

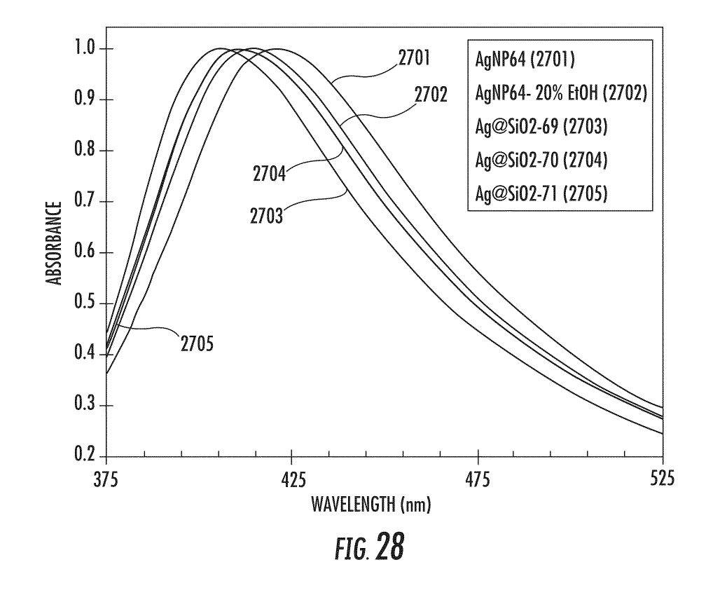

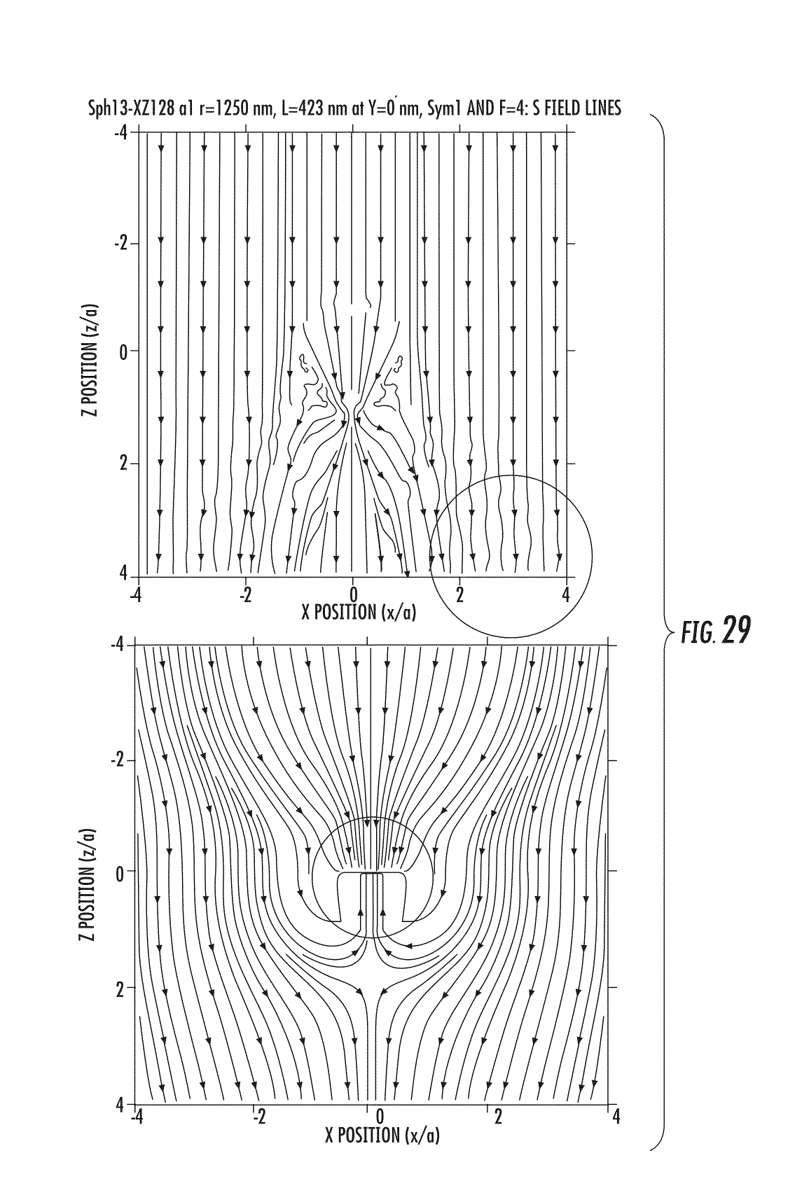

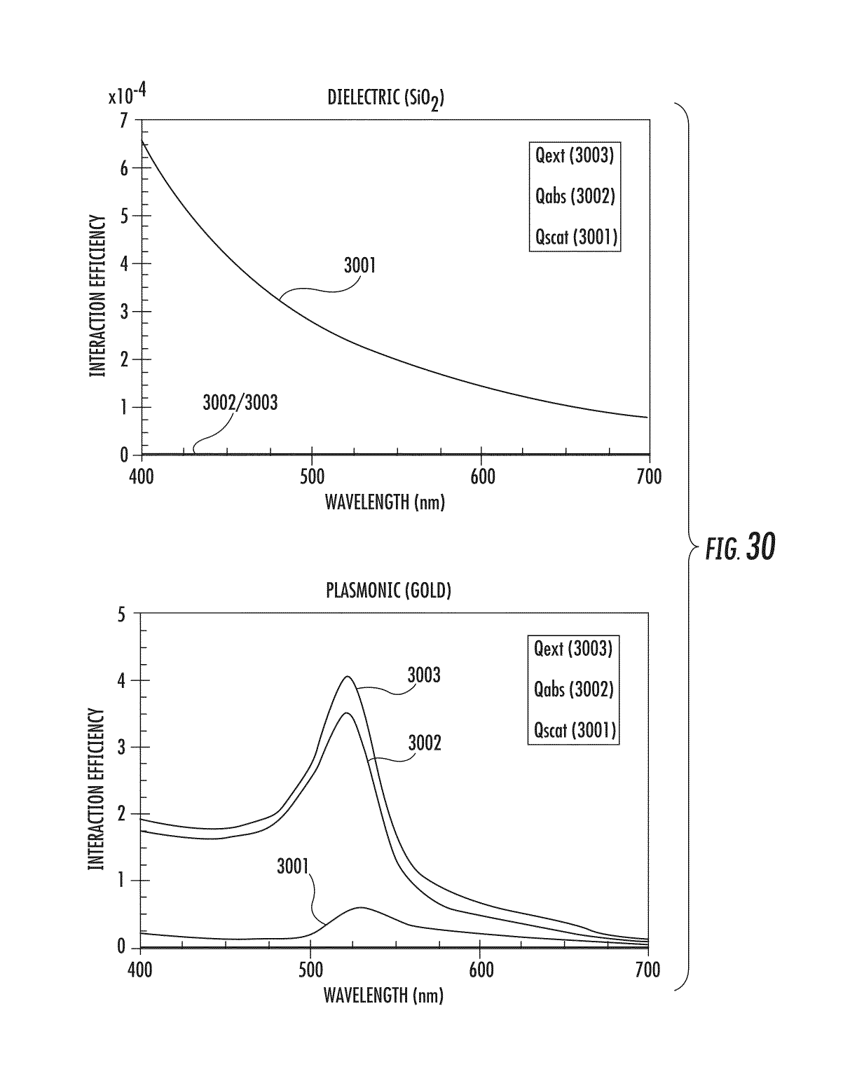

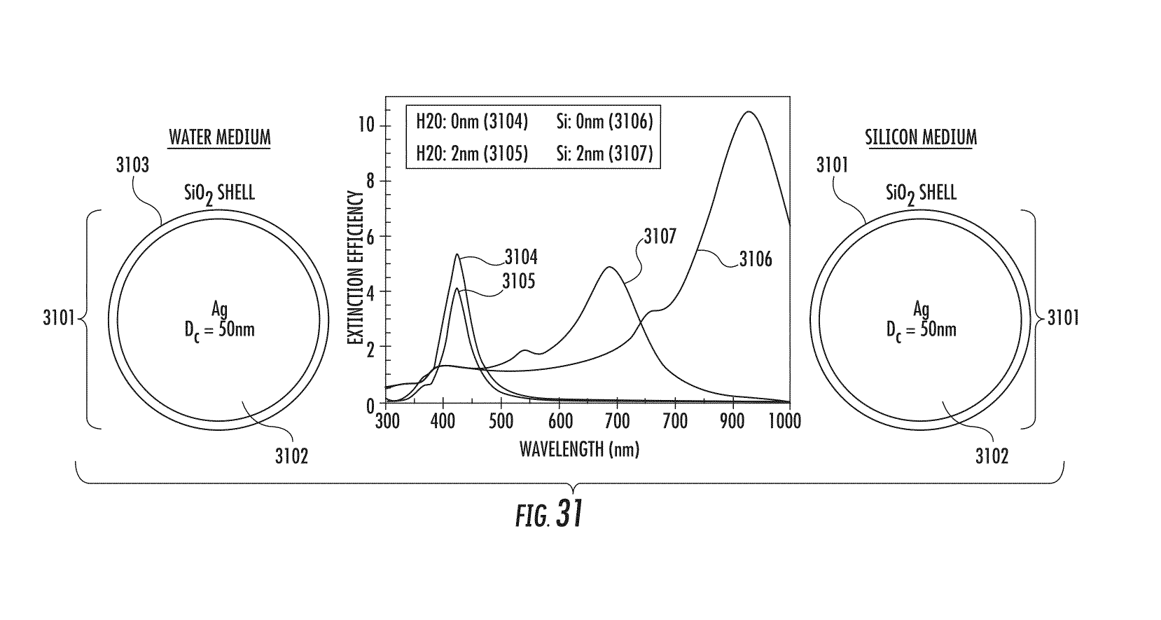

The self-assembly of nanoparticles on a surface can be accomplished by functionalizing the surface such that the nanoparticles are electrostatically bound to the surface. FIG. 24 shows a schematic of the self-assembly process. First, the electrostatic bond randomly fixes a nanoparticle to the surface, then the like charges of another citrate-stabilized particle will prevent the next particle from approaching too close. As more particles attach to the surface, the distribution begins to map the potential energy wells of the repulsive electrostatic forces between the particles.

Given the electrostatic basis, the procedure for self-assembly thus depends on the charge of the nanoparticles. Sodium citrate ions induce a negative charge on the surface of the nanoparticles and are often used to stabilize colloidal solutions of nanoparticles through electrostatic repulsion. Monolayers of specific polymeric molecules can be used to generate a positively charged ‘functionalized’ surface. The mechanism for the creation of self-assembled monolayers (SAMs) is the creation of a charged monolayer surface coating, followed by the immersion of stabilized nanoparticles with the opposite charge. The nanoparticles will stick to the surface, but there is an energy barrier to agglomeration because of the like charges on the nanoparticles. The particles will self-organize on the surface according to these influences. FIG. 24 shows a diagram of this process.

Hundreds of different tests were performed to identify conditions by which homogeneous monolayers of various nanoparticle sizes in both gold and silver nanoparticles could be formed across a 1″×1″ area. These conditions are found to be general for substrate materials including silicon and glass.

To locate nanoparticles in the center of a thin-film absorber material using standard deposition techniques, it was investigated whether time in a plasma chamber would result in the removal of the nanoparticles from the surface. In this case, nanoparticles would be self-assembled on an initial thin silicon deposition, then a subsequent layer of silicon would be grown using plasma-enhanced chemical vapor deposition (PE-CVD). It was found that while standard plasma etch and cleaning procedures would result in nanoparticle removal, the direct deposition of material on the top of the nanoparticles shielded them from removal and that the nanoparticle surface concentrations remained nearly constant. This result helped for the deposition of both dielectric and semiconductor material layers.

The term “comprising” and variations thereof as used herein is used synonymously with the term “including” and variations thereof and are open, non-limiting terms. Although the terms “comprising” and “including” have been used herein to describe various embodiments, the terms “consisting essentially of” and “consisting of” can be used in place of “comprising” and “including” to provide for more specific embodiments of the invention and are also disclosed. Other than where noted, all numbers expressing geometries, dimensions, and so forth used in the specification and claims are to be understood at the very least, and not as an attempt to limit the application of the doctrine of equivalents to the scope of the claims, to be construed in light of the number of significant digits and ordinary rounding approaches.

Unless defined otherwise, all technical and scientific terms used herein have the same meanings as commonly understood by one of skill in the art to which the disclosed invention belongs. Publications cited herein and the materials for which they are cited are specifically incorporated by reference.

1. A thin film opto-electronic conversion device, comprising: a substrate;
a pair of conductive layers arranged on the substrate;
at least one optical absorbing layer arranged between the pair of conductive layers; and
one or more types of dielectric-coated metal plasmonic nanoparticles embedded in the optical absorbing layer, wherein the plasmonic nanoparticles have at least one characteristic that increases optical absorption of the optical absorbing layer.

2. The thin film opto-electronic conversion device of claim 1, wherein at least one type of the plasmonic nanoparticles comprises:
a metal core; and
a dielectric layer, wherein the dielectric layer is coated over at least a portion of an outer surface of the metal core.

3. The thin film opto-electronic conversion device of claim 2, wherein the metal core is formed from at least one of aluminum, copper, gold, iron, silver, titanium, nickel, and zinc.

4. (canceled)

5. The thin film opto-electronic conversion device of claim 2, wherein the dielectric layer is formed from at least one of silicon dioxide, silicon nitride, diamond-like carbon, titanium dioxide, titanium nitride, iron oxide, zinc oxide, aluminum oxide, copper oxide and aluminum nitride.

6. (canceled)

7. The thin film opto-electronic conversion device of claim 2, wherein the dielectric layer reduces a charge carrier trapping effect caused by the metal core being embedded in the optical absorbing layer.

8. The thin film opto-electronic conversion device of claim 2, wherein at least one characteristic is optical resonance, and one or more wavelengths at which the optical resonance occurs can be tuned by changing one or more characteristics of the dielectric layer, nanoparticles' size, shape, material, and the distance from each other as they are embedded inside the absorbing material or a combination thereof.

9. (canceled)

10. The thin film opto-electronic conversion device of claim 1, wherein the optical absorbing layer comprises at least one of a semiconductor material, an organic material and a photosensitive dye.

11-22. (canceled)

23. The thin film opto-electronic conversion device of claim 1, wherein the plasmonic nanoparticles increase the optical absorption of the optical absorbing layer by enhancing an optical pathway of incident light through the optical absorbing layer by scattering the incoming light and changing its direction to increase optical pathway.

24-25. (canceled)

26. The thin film opto-electronic conversion device of claim 1, wherein the pair of conductive layers comprise an anode and a cathode.

27. The thin film opto-electronic conversion device of claim 1, wherein the thin film opto-electronic conversion device is at least one of a photodiode optical detector, a photovoltaic device and a photoemissive device.

28. A plasmonic nanoparticle for use with an optical absorbing material in an opto-electronic conversion device, comprising:
a metal core; and
a dielectric layer, wherein the dielectric layer is coated over at least a portion of an outer surface of the metal core, the plasmonic nanoparticles being embedded in the optical absorbing materials and having at least one characteristic that increases optical absorption of the optical absorbing material.

29-40. (canceled)

41. The plasmonic nanoparticle of claim 28, wherein the at least one characteristic is optical resonance.

42. The plasmonic nanoparticle of claim 41, wherein the optical resonance occurs at one or more wavelengths in a region a solar spectrum that are absorbed by the optical absorbing material.

43. The plasmonic nanoparticle of claim 42, wherein the optical resonance occurs at one or more wavelengths in approximately a red to near-infrared region of the solar spectrum.

44. The plasmonic nanoparticle of claim 41, wherein the optical resonance occurs at one or more wavelengths approximately near the band-gap of the optical absorbing material.

45-47. (canceled)

48. A method of manufacturing a thin film opto-electronic conversion device, comprising:
providing a substrate;
forming a pair of conductive layers arranged on the substrate;
forming at least one optical absorbing layer between the pair of conductive layers; and
embedding one or more types of dielectric-coated metal plasmonic nanoparticles in the optical absorbing layer, wherein the plasmonic nanoparticles have at least one characteristic that increases optical absorption of the optical absorbing layer.

49. The method of claim 48, wherein at least one of the plasmonic nanoparticles comprises:
a metal core; and
a dielectric layer, wherein the dielectric layer is coated over at least a portion of an outer surface of the metal core.

50-68. (canceled)

69. A method of manufacturing one or more plasmonic nanoparticles, comprising:
forming a metal core; and
coating a dielectric layer over at least a portion of an outer surface of the metal core,
wherein the plasmonic nanoparticles have at least one characteristic that increases optical absorption of an optical absorbing material when embedded therein.

70. The method of claim 69, wherein the metal core is formed by using a strong reducing agent to form metal seeds.

71. The method of claim 70, wherein the metal seeds are less than 15 nm.

72. The method of claim 69, wherein the metal seeds are grown in stages using a weak reducing agent.

73. The method of claim 69, wherein the strong reducing agent is sodium borohydride, potassium borohydride, lithium aluminum hydride, diborane, hydrazine, or hydrogen.

74-77. (canceled)
